(19) United States
(12) Patent Application Publication
(10) Pub. No.: US 2025/0280723 A1
(43) Pub. Date: Sep. 4, 2025

(54) DISPLAY DEVICE

(71) Applicant: Samsung Display Co., Ltd., Yongin-Si (KR)

(72) Inventors: Sung Won KIM, Yongin-si (KR); Jae Hyun LEE, Yongin-si (KR); Ye Eun KANG, Yongin-si (KR); Seung Rae KIM, Yongin-si (KR); Woo Geun LEE, Yongin-si (KR)

(21) Appl. No.: 18/919,444

(22) Filed: Oct. 18, 2024

(30) Foreign Application Priority Data
Mar. 4, 2024 (KR) 10-2024-0030571

(51) Int. Cl. H10K 59/88; H10K 59/131

(52) U.S. Cl. CPC H10K 59/88; H10K 59/131

(57) ABSTRACT

The present disclosure relates to a display device, and more particularly, to a display device that can prevent a short circuit between signal lines. According to an embodiment of the disclosure, a display device comprising: a substrate having a display area and a non-display area; a pixel disposed in the display area; a first driving voltage line connected to the pixel in the display area, and extending to the non-display area; an initialization voltage line connected to the pixel in the display area, extending to the non-display area and overlapping the first driving voltage line in the non-display area; and a dummy line disposed in the non-display area, and overlapping the first driving voltage line.

### CROSS-REFERENCE TO RELATED APPLICATION

This application claims priority from Korean Patent Application No. 10-2024-0030571 filed on Mar. 4, 2024 in the Korean Intellectual Property Office, and all the benefits accruing therefrom under 35 U.S.C. 119, the contents of which in its entirety are herein incorporated by reference.

### BACKGROUND

### 1. Technical Field

The present disclosure relates to a display device, and more particularly, to a display device that can prevent a short circuit between signal lines.

### 2. Description of the Related Art

An organic light emitting display device includes a display element of which luminance is changed by current, for example, an organic light emitting diode.

### SUMMARY

Aspects of the present disclosure provide a display device capable of preventing a short circuit between signal lines.

According to an embodiment of the disclosure, a display device comprises: a substrate having a display area and a non-display area; a pixel disposed in the display area; a first driving voltage line connected to the pixel in the display area, and extending to the non-display area; an initialization voltage line connected to the pixel in the display area, extending to the non-display area and overlapping the first driving voltage line in the non-display area; and a dummy line disposed in the non-display area, and overlapping the first driving voltage line.

In an embodiment, the dummy line has a floating state.

In an embodiment, the dummy line is disposed on a same layer as the initialization voltage line.

In an embodiment, the first driving voltage line comprises: a first lower voltage line disposed on the substrate, and extending in a first direction; and a first upper voltage line on the first lower voltage line, the first upper voltage line being connected to the first lower voltage line, and extending in a second direction intersecting the first direction.

In an embodiment, the dummy line overlaps the first upper voltage line.

In an embodiment, the dummy line is connected to the first lower voltage line.

In an embodiment, the dummy line is disposed on a same layer as the first lower voltage line.

In an embodiment, the display device further comprises an insulating layer between the first lower voltage line and the first upper voltage line, wherein the dummy line is disposed between the substrate and the insulating layer.

In an embodiment, the dummy line is disposed adjacent to the initialization voltage line.

In an embodiment, one end of the dummy line is disposed at one end of the substrate.

In an embodiment, the one end of the dummy line comprises a carbonized region.

In an embodiment, the dummy line has a width larger than a width of the initialization voltage line.

In an embodiment, the dummy line is provided in plural number.

In an embodiment, the plurality of dummy lines each overlap the first driving voltage line, and the plurality of dummy lines are not connected to each other.

In an embodiment, the display device further comprises a second driving voltage line overlapping the dummy line and the initialization voltage line in the non-display area.

According to an embodiment of the disclosure, a display device comprises: a substrate having a display area and a non-display area; a pixel disposed in the display area; a first driving voltage line disposed in the display area and the non-display area; an initialization voltage line disposed in the display area and the non-display area, and overlapping the first driving voltage line in the non-display area; and a dummy line overlapping the first driving voltage line in the non-display area.

In an embodiment, the dummy line has a floating state.

In an embodiment, the dummy line is disposed on a same layer as the initialization voltage line.

In an embodiment, the first driving voltage line comprises: a first lower voltage line disposed on the substrate, and extending in a first direction; and a first upper voltage line on the first lower voltage line, the first upper voltage line being connected to the first lower voltage line, and extending in a second direction intersecting the first direction.

In an embodiment, the dummy line overlaps the first upper voltage line.

In an embodiment, the dummy line is connected to the first lower voltage line.

In an embodiment, the dummy line is disposed on a same layer as the first lower voltage line.

In an embodiment, the display device further comprises an insulating layer between the first lower voltage line and the first upper voltage line, wherein the dummy line is disposed between the substrate and the insulating layer.

In an embodiment, the dummy line is disposed adjacent to the initialization voltage line.

In an embodiment, one end of the dummy line is disposed at one end of the substrate.

In an embodiment, the one end of the dummy line comprises a carbonized region.

In an embodiment, the dummy line has a width larger than a width of the initialization voltage line.

In accordance with the display device according to the present disclosure, it is possible to prevent a short circuit between signal lines.

However, aspects of the present disclosure are not restricted to the one set forth herein.

### BRIEF DESCRIPTION OF THE DRAWINGS

The above and other aspects and features of the present disclosure will become more apparent by describing in detail exemplary embodiments thereof with reference to the attached drawings.

FIG. 1 is a cross-sectional view illustrating a schematic stacked structure of a display device according to an embodiment.

FIG. 2 is a plan view illustrating a disposition of lines of a display device according to an embodiment.

FIG. 3 is a pixel circuit diagram of a display device according to an embodiment.

FIG. 4 is a plan view of a display device according to an embodiment.

FIG. 5 is an enlarged plan view of area Q1 of FIG. 4.

FIG. 6 is an enlarged plan view of area Q1 of FIG. 4.

FIG. 7 is a plan view showing a modified example of FIG. 5.

FIG. 8 is a plan view showing a modified example of FIG. 6.

FIG. 9 is an enlarged plan view of area Q3 of FIG. 4.

FIG. 10 is a cross-sectional view of a display device according to an embodiment taken along line X1-X1′ of FIGS. 5 and 6.

FIG. 11 is an enlarged cross-sectional view of area Q4 of FIG. 10.

FIG. 12 is a cross-sectional view showing a modified example of the structure shown in FIG. 11.

FIG. 13 is a cross-sectional view of a display device according to an embodiment taken along line X2-X2′ of FIG. 9.

FIG. 14 is a plan view of a dummy line and peripheral components in a base substrate including a display panel according to an embodiment.

FIG. 15 is a plan view of a display device in which a dummy panel is removed from the base substrate of FIG. 14.

FIG. 16 is a diagram for describing charge distribution by the dummy line of FIG. 14.

FIG. 17 is a diagram for describing charge distribution by the dummy line of FIG. 15.

FIG. 18 is a plan view of the dummy line and peripheral components in a base substrate including the display panel according to an embodiment.

FIG. 19 is a plan view of a display device in which the dummy panel is removed from the base substrate of FIG. 18.

FIG. 20 is a diagram illustrating a result of a simulation to which the configuration of a display device according to an embodiment is applied.

FIGS. 21 and 22 are plan views of a display device according to an embodiment.

### DETAILED DESCRIPTION OF THE EMBODIMENTS

Advantages and features of the present disclosure and methods of accomplishing the same may be understood more readily by reference to the following detailed description of exemplary embodiments and the accompanying drawings. The present disclosure may, however, be embodied in many different forms and should not be construed as being limited to the embodiments set forth herein. Rather, these embodiments are provided so that this disclosure will be thorough and complete and will fully convey the concept of the present disclosure to those skilled in the art, and the present disclosure will only be defined by the appended claims.

It will be understood that when an element or layer is referred to as being “on” another element or layer, the element or layer can be directly on another element or layer or intervening elements or layers. Like reference numerals refer to like elements throughout the specification. Shapes, sizes, ratios, angles, numbers, etc. disclosed in the drawings for describing embodiments are merely an example, and the present disclosure is not limited to the illustrated details.

It will be understood that, although the terms first, second, third, etc., may be used herein to describe various elements, these elements should not be limited by these terms. These terms are only used to distinguish one element from another element. Thus, a first element discussed below could be termed a second element without departing from the teachings of the present disclosure.

Features of various embodiments of the present disclosure may be partially or entirely coupled to or combined with each other, and may be inter-operated and driven in technically various ways. The embodiments may be implemented independently from each other, or may be implemented together in a co-dependent relationship.

Hereinafter, specific embodiments will be described with reference to the accompanying drawings.

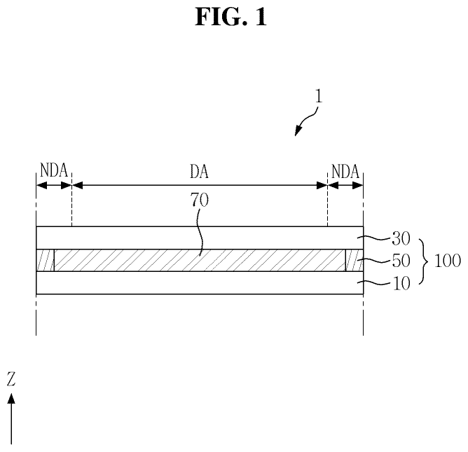

FIG. 1 is a cross-sectional view illustrating a schematic stacked structure of a display device 1 according to an embodiment.

Referring to FIG. 1, the display device 1 may be applied to a variety of electronic apparatuses, i.e., small and medium electronic devices such as a tablet PC, a smartphone, a car navigation unit, a camera, a center information display (CID) provided in a vehicle, a wristwatch-type electronic device, a personal digital assistant (PDA), a portable multimedia player (PMP) and a game console, and medium and large electronic devices such as a television, an external billboard, a monitor, a personal computer and a laptop computer. These are merely suggested as examples, but the display device 1 may also be applied to other electronic devices without departing from the present disclosure.

The display device 1 may include a display area DA displaying an image and a non-display area NDA not displaying an image. In some embodiments, the non-display area NDA may be located around the display area DA and may surround the display area DA. The image displayed in the display area DA may be recognized by a user in an arrow direction in the drawing in the third direction Z.

A schematic stacked structure of the display device 1 is described. In some embodiments, the display device 1 may include a display panel 100 as shown in FIG. 1. The display panel 100 may include a display substrate 10, a color conversion substrate 30 facing the display substrate 10, a sealing member 50 that couples the display substrate 10 and the color conversion substrate 30, and a filler 70 filled between the display substrate 10 and the color conversion substrate 30.

The display substrate 10 may include elements and circuits for displaying an image, for example, a pixel circuit such as a switching element, a self-light emitting element, and a pixel defining layer defining an emission area and a non-emission area, which will be described later, in the display area DA. In an exemplary embodiment, the self-light emitting element may include at least one of an organic light emitting diode, a quantum dot light emitting diode, an inorganic material-based micro light emitting diode (e.g., micro LED), or an inorganic material-based light emitting diode having a nano size (e.g., nano LED). Hereinafter, for simplicity of description, a case where the self-light emitting element is an organic light emitting element will be described as an example.

The color conversion substrate 30 may be positioned on the display substrate 10 to face the display substrate 10. In some embodiments, the color conversion substrate 30 may include a color conversion pattern for converting the color of incident light. In some embodiments, the color conversion substrate 30 may include at least one of a color filter and a wavelength conversion pattern as the color conversion pattern. In some embodiments, the color conversion substrate 30 may include both the color filter and the wavelength conversion pattern.

The sealing member 50 may be positioned between the display substrate 10 and the color conversion substrate 30 in the non-display area NDA. The sealing member 50 may be disposed along the edges of the display substrate 10 and the color conversion substrate 30 in the non-display area NDA to surround the display area DA in plan view. The display substrate 10 and the color conversion substrate 30 may be coupled to each other by the sealing member 50.

In some embodiments, the sealing member 50 may be made of an organic material. For example, the sealing member 50 may be made of epoxy resin, but is not limited thereto. In some other embodiments, the sealing member 50 may be applied in the form of a frit including glass or the like.

The filler 70 may be positioned in the space between the display substrate 10 and the color conversion substrate 30 surrounded by the sealing member 50. The filler 70 may fill the space between the display substrate 10 and the color conversion substrate 30.

In some embodiments, the filler 70 may be made of a material capable of transmitting light. In some embodiments, the filler 70 may be made of an organic material. For example, the filler 70 may be made of a silicon-based organic material, an epoxy-based organic material, or a mixture of a silicon-based organic material and an epoxy-based organic material.

In some embodiments, the filler 70 may be made of a material having an extinction coefficient of substantially zero. There is a correlation between a refractive index and an extinction coefficient, and as the refractive index decreases, the extinction coefficient also decreases. In addition, when the refractive index is 1.7 or less, the extinction coefficient may substantially converge to zero. In some embodiments, the filler 70 may be made of a material having a refractive index of 1.7 or less, so that it is possible to prevent or minimize light provided from the self-light emitting element from being absorbed while passing through the filler 70. In some embodiments, the filler 70 may be made of an organic material having a refractive index of 1.4 to 1.6.

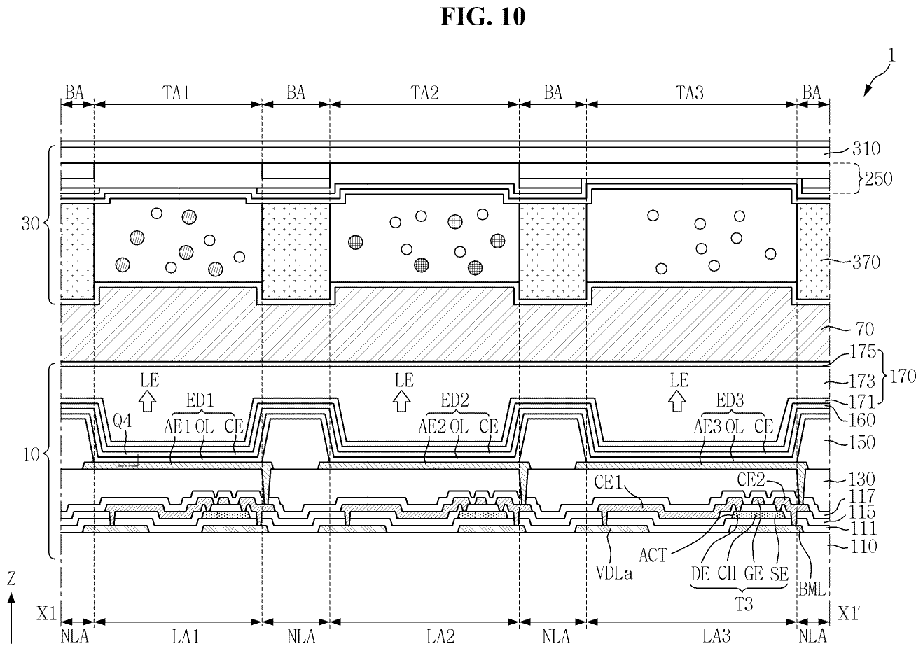

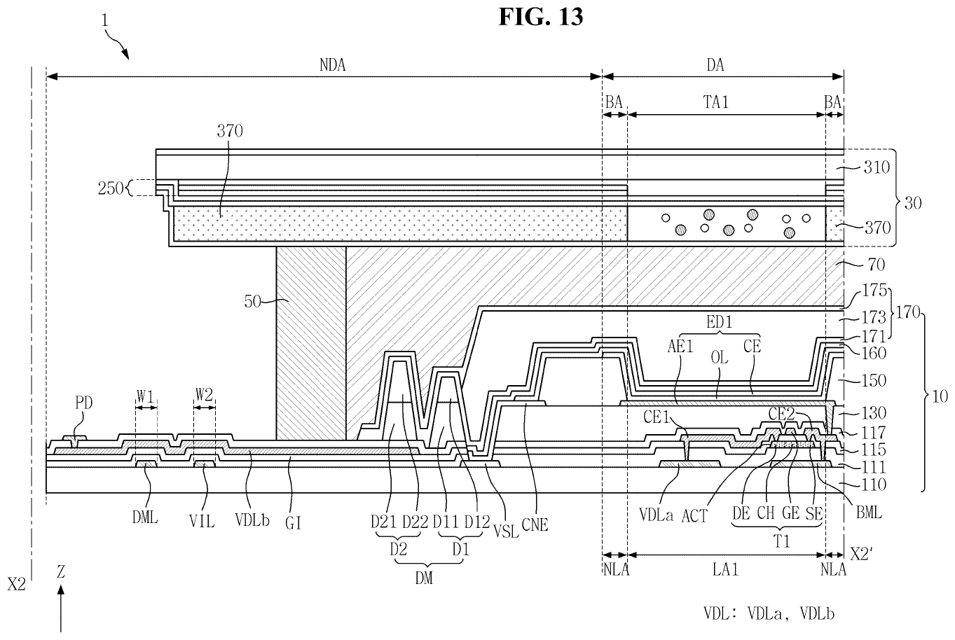

Although FIG. 1 illustrates that the display device 1 includes the display substrate 10, the color conversion substrate 30, the sealing member 50, and the filler 70, in some embodiments, the display device 1 may not include the sealing member 50 and the filler 70, and components of the color conversion substrate 30 except a second substrate 310, e.g., see FIGS. 10, 13, may be disposed on the display substrate 10.

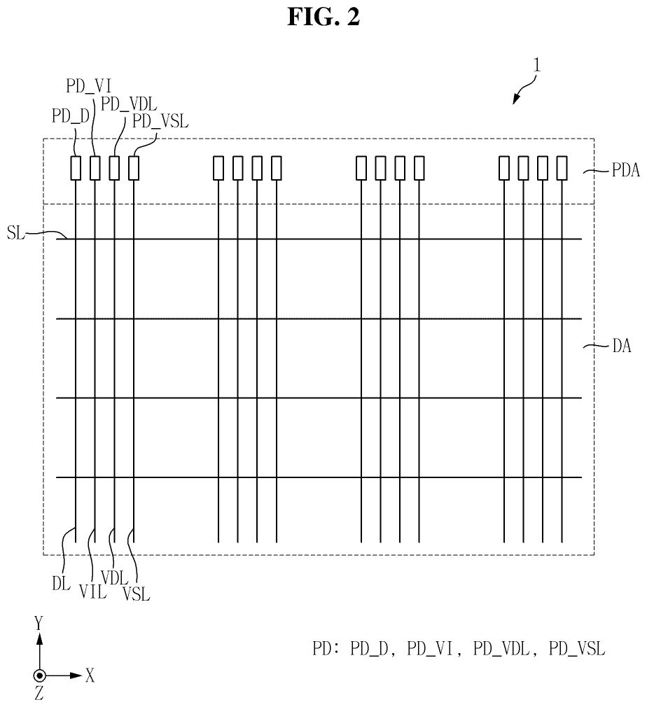

FIG. 2 is a plan view illustrating a disposition of lines of a display device 1 according to an embodiment.

Referring to FIG. 2, the display device 1 may include a plurality of lines. The lines of the display device may include a plurality of scan lines SL, a plurality of data lines DL, a plurality of initialization voltage lines VIL, a plurality of first driving voltage lines VDL, and a plurality of second driving voltage lines VSL. Although not shown in the drawing, other wires may be further provided in the display device.

The data lines DL, the initialization voltage lines VIL, the first driving voltage lines VDL, and the second driving voltage lines VSL may extend to the non-display area to be connected to pad electrodes PD disposed in a pad area PDA of the non-display area NDA. The pad electrodes PD may include data pad electrodes PD_D connected to the data lines DL, initialization voltage pad electrodes PD_VI connected to the initialization voltage lines VIL, first voltage pad electrodes PD_VDL connected to the first driving voltage lines VDL, and second voltage pad electrodes PD_VSL connected to the second driving voltage lines VSL.

The term “connected” as used herein may mean not only that one member is connected to another member through a physical contact, but also that one member is connected to another member through yet another member. This may also be understood as one part and the other part as integral elements are connected into an integrated element via another element. Furthermore, if one element is connected to another element, this may be construed as a meaning including an electrical connection via another element in addition to a direct connection in physical contact.

The drawing exemplifies that each of the pad electrodes PD is disposed on the pad area PDA disposed on the upper side of the display area DA, but is not limited thereto. Some of the plurality of pad electrodes PD may be disposed in any one area on the lower side or on the left and right sides of the display area DA.

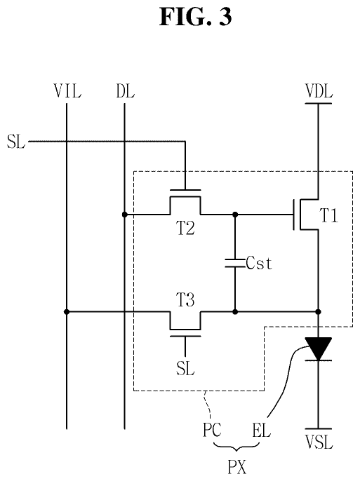

The display device 1 may include a plurality of pixels (e.g., see pixel PX in FIG. 3) disposed in the display area DA. The above-described lines may pass through each pixel PX or the vicinity thereof to apply a driving signal to each pixel PX.

A plurality of adjacent pixels PX may constitute one unit pixel. In this case, three adjacent pixels PX may provide light of different colors. For example, the three adjacent pixels PX may provide red light, green light, and blue light, respectively.

FIG. 3 is a pixel circuit diagram of a display device 1 according to an embodiment.

Referring to FIG. 3, the pixel PX of the display device 1 according to an embodiment may include a light emitting diode EL and a pixel circuit PC connected to the light emitting diode EL. According to some embodiments, the pixel circuit PC may include three transistors T1, T2, and T3 and one storage capacitor Cst.

The light emitting diode EL emits light by a current supplied through a first transistor T1. The light emitting diode EL includes a first electrode, a second electrode, and at least one light emitting element disposed between them. The light emitting element may emit light of a specific wavelength band by electrical signals transmitted from the first electrode and the second electrode.

One end of the light emitting diode EL may be connected to the source electrode of the first transistor T1, and the other end thereof may be connected to the second driving voltage line VSL to which a low potential voltage (hereinafter, a second driving voltage) lower than a high potential driving voltage (hereinafter, a first driving voltage) of the first driving voltage line VDL is supplied.

The first transistor T1 adjusts a current flowing from the first driving voltage line VDL, to which the first power voltage is supplied, to the light emitting diode EL according to the voltage difference between the gate electrode and the source electrode. For example, the first transistor T1 may be a driving transistor for driving the light emitting diode EL. The gate electrode of the first transistor T1 may be connected to the source electrode of the second transistor T2, the source electrode of the first transistor T1 may be connected to the first electrode of the light emitting diode EL, and the drain electrode of the first transistor T1 may be connected to the first driving voltage line VDL to which the first power voltage is applied.

The second transistor T2 is turned on by a scan signal of the scan line SL to connect the data line DL to the gate electrode of the first transistor T1. The gate electrode of the second transistor T2 may be connected to the scan line SL, the source electrode of the second transistor T2 may be connected to the gate electrode of the first transistor T1, and the drain electrode of the second transistor T2 may be connected to the data line DL.

The third transistor T3 is turned on by a scan signal of the scan line SL to connect the initialization voltage line VIL to one end of the light emitting diode EL. The gate electrode of the third transistor T3 may be connected to the scan line SL, the drain electrode of the third transistor T3 may be connected to the initialization voltage line VIL, and the source electrode of the third transistor T3 may be connected to one end of the light emitting diode EL or to the source electrode of the first transistor T1.

In an embodiment, the source electrode and the drain electrode of each of the transistors T1, T2, and T3 are not limited to those described above, and vice versa. Each of the transistors T1, T2, and T3 may be formed of a thin film transistor. In FIG. 3, each of the transistors T1, T2, and T3 has been described as being formed of an N-type metal oxide semiconductor field effect transistor (MOSFET), but is not limited thereto. For example, each of the transistors T1, T2, and T3 may be formed of a P-type MOSFET. In an embodiment, some of the transistors T1, T2, and T3 may be formed of an N-type MOSFET and the others may be formed of a P-type MOSFET.

The storage capacitor Cst is formed between the gate electrode and the source electrode of the first transistor T. The storage capacitor Cst stores a difference voltage between a gate voltage and a source voltage of the first transistor T1.

Although the embodiment of FIG. 3 illustrates that the gate electrodes of the second transistor T2 and the third transistor T3 are connected to the same scan line SL and, thus, the second transistor T2 and the third transistor T3 are simultaneously turned on by the scan signal applied from the same scan line, the present disclosure is not limited thereto, and the gate electrode of the second transistor T2 may be connected to any one scan line SL, and the gate electrode of the third transistor T3 may be connected to another scan line SL different from the any one scan line SL.

The number of transistors and capacitors in the pixel circuit PC may vary. According to an embodiment, the pixel circuit PC of the pixel PX may have various other modified structures such as a 2T1C structure including two transistors and one storage capacitor, a 7T1C structure including seven transistors and one storage capacitor, and a 6T1C structure including 6 transistors and one storage capacitor.

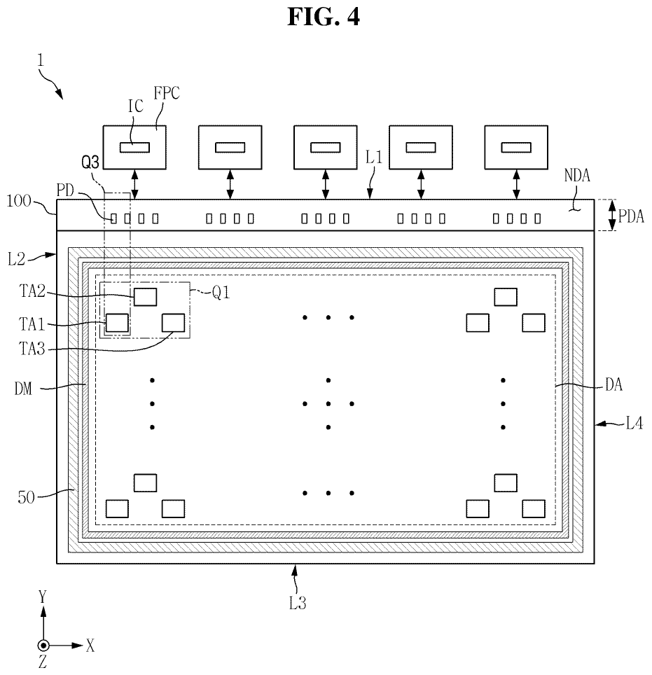

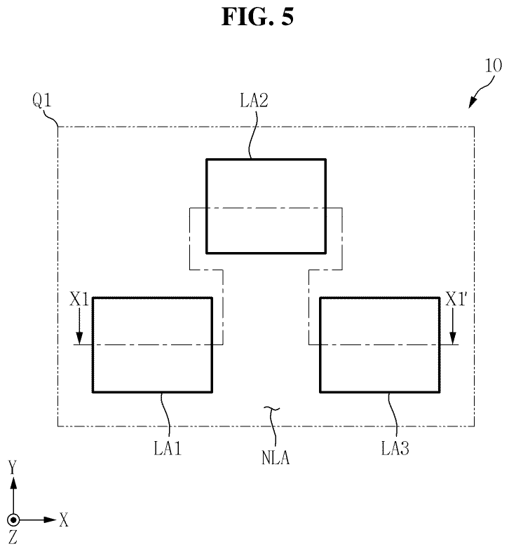

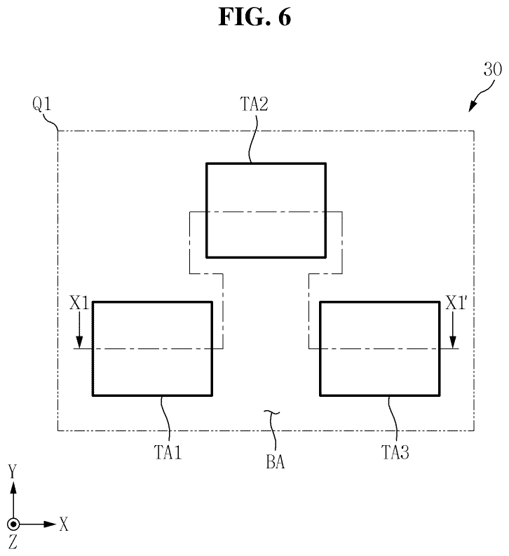

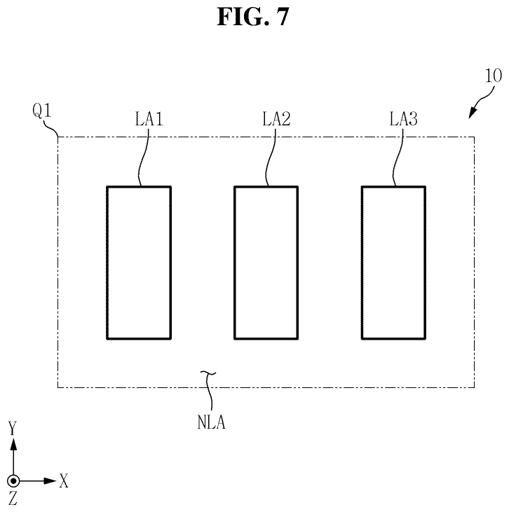

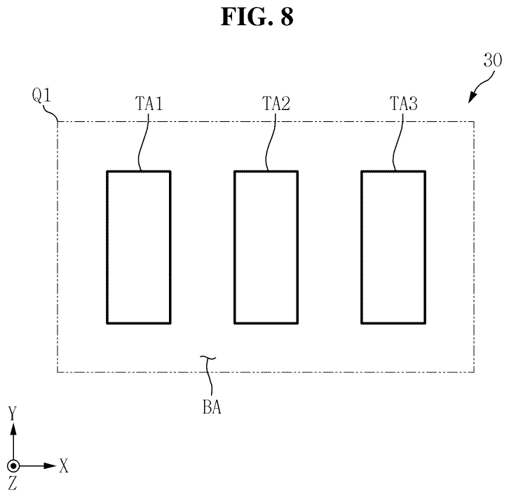

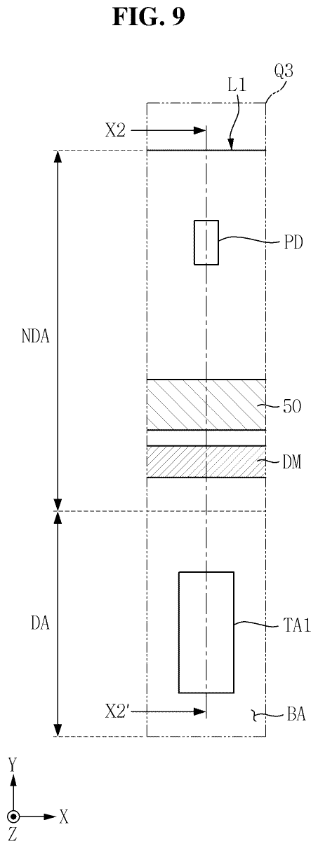

FIG. 4 is a plan view of a display device 1 according to an embodiment. FIG. 5 is an enlarged plan view of area Q1 of FIG. 4, and more specifically, is a schematic plan view of a display substrate 10 included in the display device 1 of FIG. 4. FIG. 6 is an enlarged plan view of area Q1 of FIG. 4, and more specifically, is a schematic plan view of a color conversion substrate 30 included in the display device 1 of FIG. 4. FIG. 7 is a plan view showing a modified example of FIG. 5. FIG. 8 is a plan view showing a modified example of FIG. 6. FIG. 9 is an enlarged plan view of area Q3 of FIG. 4.

Referring further to FIGS. 4 to 9 in addition to FIG. 1, in some embodiments, as shown in FIG. 4, the display device 1 may have a rectangular shape in plan view. The display device 1 may include a first side L1 and a third side L3 extending in the first direction (X direction) and a second side L2 and a fourth side L4 extending in the second direction (Y direction) intersecting the first direction (X direction). The corners where the sides of the display device 1 meet may be right-angled, but is not limited thereto. In some embodiments, the lengths of the first side L1 and the third side L3 and the lengths of the second side L2 and the fourth side L4 may be different from each other. For example, the first side L1 and the third side L3 may be relatively longer than the second side L2 and the fourth side L4. The planar shape of the display device 1 is not limited to the exemplified one, but may have a circular shape or other shapes.

In some embodiments, the display device 1 may further include a flexible circuit board FPC and a driving chip IC.

As shown in FIG. 5, in the display area DA, a plurality of emission areas LA1, LA2, and LA3 and a non-emission area NLA may be defined on the display substrate 10.

In some embodiments, a first emission area LA1, a second emission area LA2, and a third emission area LA3 may be defined in the display area DA of the display substrate 10. The first emission area LA1, the second emission area LA2, and the third emission area LA3 may be areas in which light generated by the light emitting element of the display substrate 10 is emitted to the outside of the display substrate 10, and the non-emission area NLA may be an area in which light is not emitted to the outside of the display substrate 10. In some embodiments, the non-emission area NLA may surround each of the first emission area LA1, the second emission area LA2, and the third emission area LA3 in the display area DA.

In some embodiments, the light emitted to the outside in the first emission area LA1, the second emission area LA2, and the third emission area LA3 may be light of a third color. In some embodiments, the light of the third color may be blue light, and may have a peak wavelength within a range of about 440 nm to about 480 nm. Here, the peak wavelength means a wavelength at which the intensity of light is maximum.

In some embodiments, the first emission area LA1, the second emission area LA2, and the third emission area LA3 may form one group, and a plurality of groups may be defined in the display area DA.

As illustrated in FIG. 5, the first emission area LA1 and the third emission area LA3 may be adjacent to each other along the first direction (X direction), and the second emission area LA2 may be located at one side of the first emission area LA1 and the third emission area LA3 along the second direction (Y direction). However, the present disclosure is not limited thereto, and the arrangement of the first emission area LA1, the second emission area LA2, and the third emission area LA3 may be variously changed. For example, as illustrated in FIG. 5, the first emission area LA1, the second emission area LA2, and the third emission area LA3 may be sequentially positioned along the first direction (X direction). In some embodiments, in the display area DA, the first emission area LA1, the second emission area LA2, and the third emission area LA3 may form one group and be repeatedly disposed along the first direction (X direction) and the second direction (Y direction).

Hereinafter, a case in which the first emission area LA1, the second emission area LA2, and the third emission area LA3 are disposed as shown in FIG. 5 will be described as an example.

As shown in FIG. 6, in the display area DA, a plurality of light transmitting areas TA1, TA2, and TA3 and a light blocking area BA may be defined on the color conversion substrate 30. The light transmitting areas TA1, TA2, and TA3 may be regions where light emitted from the display substrate 10 passes through the color conversion substrate 30 and is provided to the outside of the display device 1. The light blocking area BA may be a region where light emitted from the display substrate 10 does not transmit.

In some embodiments, a first light transmitting area TA1, a second light transmitting area TA2, and a third light transmitting area TA3 may be defined on the color conversion substrate 30.

The first light transmitting area TA1 may correspond to or overlap the first emission area LA1. Similarly, the second light transmitting area TA2 may correspond to or overlap the second emission area LA2, and the third light transmitting area TA3 may correspond to or overlap the third emission area LA3.

When the first emission area LA1 and the third emission area LA3 may be adjacent to each other along the first direction (X direction) and the second emission area LA2 is located at one side of the first emission area LA1 and the third emission area LA3 along the second direction (Y direction) as shown in FIG. 5, the first light transmitting area TA1 and the third light transmitting area TA3 may be adjacent to each other along the first direction (X direction) and the second light transmitting area TA2 may be located at one sides of the first light transmitting area TA1 and the third light transmitting area TA3 along the second direction (Y direction) as shown in FIG. 4.

In some embodiments, when the first emission area LA1, the second emission area LA2, and the third emission area LA3 are sequentially positioned along the first direction (X direction) as shown in FIG. 7, the first light transmitting area TA1, the second light transmitting area TA2, and the third light transmitting area TA3 may also be sequentially positioned along the first direction (X direction) as shown in FIG. 8.

In some embodiments, each of the first light transmitting area TA1, the second light transmitting area TA2, and the third light transmitting area TA3 may have a quadrilateral shape in plan view. For example, the quadrilateral shape may be a rectangular shape or a square shape. However, the present disclosure is not limited thereto, and each of the first light transmitting area TA1, the second light transmitting area TA2, and the third light transmitting area TA3 may have a circular shape, an elliptical shape, or another polygonal shape in plan view.

In some embodiments, the light of the third color provided from the display substrate 10 may pass through the first light transmitting area TA1, the second light transmitting area TA2, and the third light transmitting area TA3 and be provided to the outside of the display device 1. When the light emitted from the first light transmitting area TA1 to the outside of the display device 1 is referred to as first emission light, the light emitted from the second light transmitting area TA2 to the outside of the display device 1 is referred to as second emission light and the light emitted from the third light transmitting area TA3 to the outside of the display device 1 is referred to as third emission light, the first emission light may be light of a first color, the second emission light may be light of a second color different from the first color, and the third emission light may be light of a third color. In some embodiments, the light of the third color may be blue light having a wavelength range of 380 nm to 500 nm and having a peak wavelength within a range of 440 nm to 480 nm, and the light of the first color may be red light having a wavelength range of 600 nm to 780 nm and having a peak wavelength within a range of 610 nm to 650 nm. Further, the light of the second color may be green light having a wavelength range of 500 nm to 600 nm and having a peak wavelength within a range of 510 nm to 550 nm.

The light blocking area BA may be positioned around the first light transmitting area TA1, the second light transmitting area TA2, and the third light transmitting area TA3 of the color conversion substrate 30 in the display area DA. In some embodiments, the light blocking area BA may surround the first light transmitting area TA1, the second light transmitting area TA2, and the third light transmitting area TA3. Further, the light blocking area BA may also be positioned in the non-display area NDA of the display device 1.

As shown in FIG. 6, in the display area DA, the plurality of light transmitting areas TA1, TA2, and TA3 and the light blocking area BA may be defined on the color conversion substrate 30. The light transmitting areas TA1, TA2, and TA3 may be regions where light emitted from the display substrate 10 passes through the color conversion substrate 30 and is provided to the outside of the display device 1. The light blocking area BA may be a region where light emitted from the display substrate 10 does not transmit.

Referring to FIGS. 4 and 9, a dam member DM and the sealing member 50 may be disposed in the non-display area NDA of the display device 1.

The dam member DM may block an organic material (or monomer) from overflowing in a process of forming an encapsulation layer disposed in the display area DA, so that it is possible to prevent the organic material of the encapsulation layer from extending toward the edge of the display device 1.

In some embodiments, the dam member DM may be disposed to completely surround the display area DA in plan view.

The sealing member 50 may couple the display substrate 10 and the color conversion substrate 30 to each other as described above.

The sealing member 50 may be positioned more outward than the dam member DM in the non-display area NDA, and may be disposed to completely surround the dam member DM and the display area DA in plan view.

The non-display area NDA of the display device 1 may include the pad area PDA, and the plurality of connection pad electrodes PD described above may be positioned in the pad area PDA.

The display substrate 10 (see FIG. 1) of the display device 1 may include the dam member DM and the connection pad electrode PD described above.

The flexible circuit board FPC may be connected to the connection pad electrode PD. The flexible circuit board FPC may electrically connect the display substrate 10 (see FIG. 1) and a circuit board that provides a signal and power for driving the display device 1.

The driving chip IC may be electrically connected to the circuit board to receive data and a signal. In some embodiments, the driving chip IC may be a data driving chip, and may receive a data control signal and image data from the circuit board and generate and output a data voltage corresponding to the image data.

In some embodiments, the driving chip IC may be mounted on the flexible circuit board FPC. For example, the driving chip IC may be mounted on the flexible circuit board FPC in the form of a chip on film (COF).

The data voltage provided from the driving chip IC, the power provided from the circuit board, and the like may be transmitted to the pixel circuit and the like of the display substrate 10 (see FIG. 1) via the flexible circuit board FPC and the connection pad electrode PD.

Hereinafter, the structure of the display device 1 will be described in more detail.

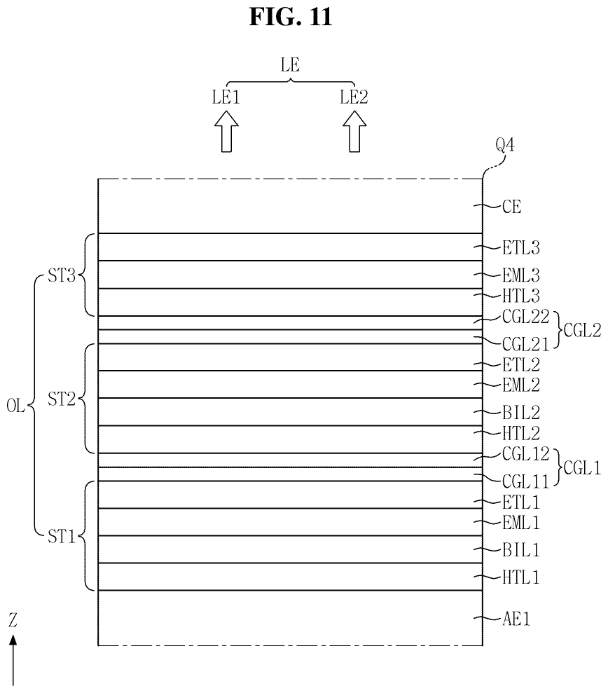

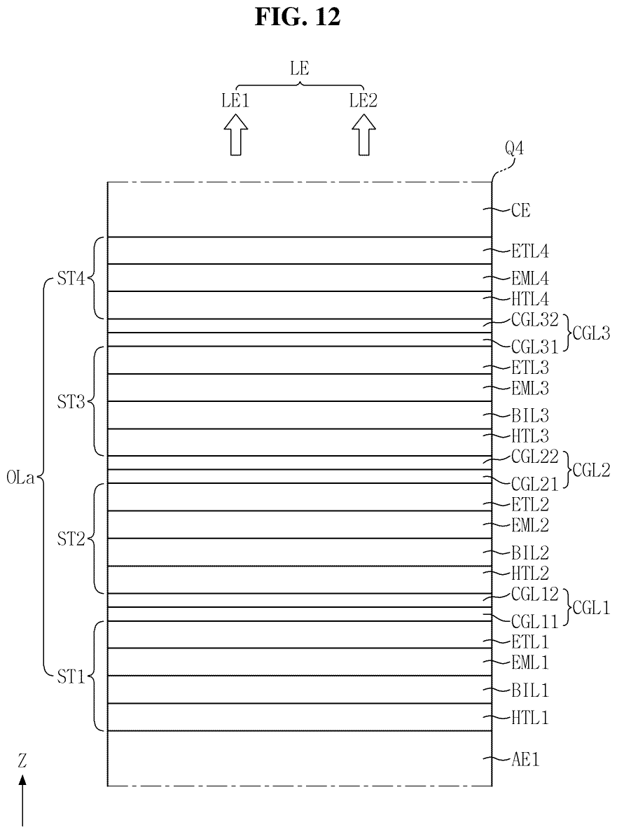

FIG. 10 is a cross-sectional view of the display device 1 according to an embodiment taken along line X1-X1′ of FIGS. 5 and 6. FIG. 11 is an enlarged cross-sectional view of area Q4 of FIG. 10. FIG. 12 is a cross-sectional view showing a modified example of the structure shown in FIG. 11. FIG. 13 is a cross-sectional view of the display device 1 according to an embodiment taken along line X2-X2′ of FIG. 9.

Referring further to FIGS. 10 to 13 in addition to FIGS. 1 to 9, the display device 1 may include the display substrate 10 and the color conversion substrate 30 as described above, and may further include the filler 70 positioned between the display substrate 10 and the color conversion substrate 30.

Hereinafter, the display substrate 10 will be described.

A first substrate 110 of the display substrate 10 may be made of a light transmitting material. In some embodiments, the first substrate 110 may be a glass substrate or a plastic substrate. When the first substrate 110 is a plastic substrate, the first substrate 110 may have flexibility.

In some embodiments, in the display area DA, the plurality of emission areas LA1, LA2, and LA3 and the non-emission area NLA may be defined at the first substrate 110 as described above.

In some embodiments, the first side L1, the second side L2, the third side L3, and the fourth side L4 of the display device 1 may be the same as four sides of the first substrate 110. That is, the first side L1, the second side L2, the third side L3, and the fourth side L4 of the display device 1 may be referred to as the first side L1, the second side L2, the third side L3, and the fourth side L4 of the first substrate 110, respectively.

A first conductive layer may be positioned on the first substrate 110. The first conductive layer may include a lower light blocking layer BML, a first lower voltage line VDLa, the initialization voltage line VIL, and a dummy line DML. The lower light blocking layer BML may overlap an active layer ACT, which will be described later, in the thickness direction (z direction). In addition, although not shown, since a part of the lower light blocking layer BML may overlap a second conductive layer which will be described later, the storage capacitor Cst may be formed in the area where the lower light blocking layer BML overlaps the second conductive layer.

The lower light blocking layer BML may block incidence of external light or light from the light emitting diode EL into the active layer ACT, so that it is possible to prevent a leakage current from occurring due to light in a thin film transistor to be described later or to reduce a leakage current.

In some embodiments, the lower light blocking layer BML may be made of a material that blocks light and has conductivity. For example, the lower light blocking layer BML may include a single material of metal such as silver (Ag), nickel (Ni), gold (Au), platinum (Pt), aluminum (Al), copper (Cu), molybdenum (Mo), titanium (Ti), or neodium (Nd), or an alloy thereof. In some embodiments, the lower light blocking layer BML may have a single-layer or multilayer structure. For example, when the lower light blocking layer BML has a multilayer structure, the lower light blocking layer BML may have a stacked structure of titanium (Ti)/copper (Cu)/indium tin oxide (ITO), or a stacked structure of titanium (Ti)/copper (Cu)/aluminum oxide (Al₂O₃), but is not limited thereto. In some embodiments, the first lower voltage line VDLa, the initialization voltage line VIL, and the dummy line DML may be made of the same material as the lower light blocking layer BML described above.

According to some embodiments, the dummy line DML may prevent a large amount of charges from accumulating in an overlapping area OVA of a first upper voltage line VDLb and the initialization voltage line VIL, which will be described later, thereby preventing a short circuit between the first upper voltage line VDLb and the initialization voltage line VIL.

In some embodiments, a width W1 of the dummy line DML may be larger than a width W2 of the initialization voltage line VIL. Accordingly, the overlapping area of the dummy line DML and the first upper voltage line VDLb, which will be described later, may be larger than the overlapping area of the initialization voltage line VIL and the first upper voltage line VDLb. In this case, the charges of the first upper voltage line VDLb, which will be described later, may be better distributed to the dummy line DML than to the initialization voltage line VIL. When charges are collectively accumulated in the overlapping area between the dummy line DML and the first upper voltage line VDLb and thus an insulating layer (e.g., a buffer layer 111 and a gate insulating layer 115) between the dummy line DML and the first upper voltage line VDLb is damaged, the first upper voltage line VDLb and the dummy line DML may be connected to each other. In other words, the first upper voltage line VDLb and the dummy line DML may be short-circuited. Since the dummy line DML is a floating line to which no signal is applied, no circuit problem occurs even when the first upper voltage line VDLb and the dummy line DML are short-circuited. In addition, when the first upper voltage line VDLb and the dummy line DML are short-circuited, the area of the first upper voltage line VDLb increases, thereby increasing the charge distribution effect described above.

The buffer layer 111 may be positioned on the first conductive layer. The buffer layer 111 may be positioned on the first substrate 110 and may be disposed in the display area DA and the non-display area NDA. The buffer layer 111 may block foreign substances or moisture permeating through the first substrate 110. For example, the buffer layer 111 may include an inorganic material such as SiO₂, SiNx, or SiON, and may be formed as a single layer or multiple layers.

The active layer ACT may be positioned on the buffer layer 111. The active layer ACT may be disposed in the display area DA and the non-display area NDA. The active layer ACT may be disposed to correspond to each of the first emission area LA1, the second emission area LA2, and the third emission area LA3 in the display area DA, and may constitute the above-described lines SL, DL, VIL, VDL, and VSL. The active layer ACT may constitute an active layer of thin film transistors T1, T2, and T3 (see FIG. 3). The following description is directed to the case where the active layer ACT is used as an active layer of the thin film transistors T1, T2, and T3. The active layer ACT may include a source electrode SE, a drain electrode DE, and a channel region CH, which will be described later. The channel region CH may be formed in an area of the active layer ACT that overlaps a gate electrode GE, which will be described later, and the source electrode SE and the drain electrode DE may be formed on both sides of the channel region CH.

In some embodiments, the active layer ACT may include an oxide semiconductor. For example, the active layer ACT may be formed of a Zn oxide-based material, e.g., Zn oxide, In—Zn oxide, or Ga—In—Zn oxide, and may also be an In—Ga—Zn—O (IGZO) semiconductor containing a metal such as indium (In) or gallium (Ga). However, the present disclosure is not limited thereto, and the active layer ACT may include amorphous silicon, polysilicon, or the like.

The gate insulating layer 115 may be positioned on the active layer ACT. In some embodiments, the gate insulating layer 115 may be positioned in the display area DA and the non-display area NDA. In some embodiments, the gate insulating layer 115 may include an inorganic material such as SiO₂, SiNx, SiON, Al₂O₃, TiO₂, Ta₂O, HfO₂, ZrO₂, or the like.

A second conductive layer (or gate conductive layer) may be positioned on the gate insulating layer 115, and the second conductive layer may include the gate electrode GE, the first upper voltage line VDLb, a first connection electrode CE1, and a second connection electrode CE2. The gate electrode GE, the first connection electrode CE1, and the second connection electrode CE2 may be located in the display area DA to overlap the active layer ACT. As shown in FIG. 13, the first upper voltage line VDLb may overlap the dummy line DML and the initialization voltage line VIL.

The gate electrode GE may overlap the channel region CH of the active layer ACT. The channel region CH may be spaced apart from the gate electrode GE with the gate insulating layer 115 therebetween.

The second connection electrode CE2 may be connected to the source electrode SE and the lower light blocking layer BML. For example, one side of the second connection electrode CE2 may be connected to the source electrode SE of the active layer ACT through a contact hole penetrating the gate insulating layer 115, and the other side of the second connection electrode CE2 may be connected to the lower light blocking layer BML through a contact hole penetrating the gate insulating layer 115 and the buffer layer 111.

The first connection electrode CE1 may be connected to the drain electrode DE and the first lower voltage line VDLa. For example, one side of the first connection electrode CE1 may be connected to the drain electrode DE of the active layer ACT through a contact hole penetrating the gate insulating layer 115, and the other side of the first connection electrode CE1 may be connected to the first lower voltage line VDLa through a contact hole penetrating the gate insulating layer 115 and the buffer layer 111.

The first upper voltage line VDLb may be connected to the aforementioned first lower voltage line VDLa. For example, the first upper voltage line VDLb may be connected to the first lower voltage line VDLa through a contact hole penetrating the gate insulating layer 115 and the buffer layer 111. The first upper voltage line VDLb may constitute the aforementioned first driving voltage VDL line together with the first lower voltage line VDLa. In other words, the first driving voltage line VDL may include the first lower voltage line VDLa and the first upper voltage line VDLb. The first lower voltage line VDLa may intersect the first upper voltage line VDLb in the display area DA. For example, the plurality of first lower voltage lines VDLa may extend in the first direction, and the plurality of first upper voltage lines VDLb may extend in the second direction. Accordingly, the first driving voltage line VDL including the plurality of first lower voltage lines VDLa and the plurality of the first upper voltage lines VDLb may have a mesh form in the display area DA. According to some embodiments, the first upper voltage line VDLb may overlap the dummy line DML and the initialization voltage line VIL as shown in the example illustrated in FIG. 13.

The second conductive layer, for example, the gate electrode GE, the first upper voltage line VDLb, the dummy line DML, the first connection electrode CE1, and the second connection electrode CE2 may contain one or more materials of aluminum (Al), platinum (Pt), palladium (Pd), silver (Ag), magnesium (Mg), gold (Au), nickel (Ni), neodymium (Nd), iridium (Ir), chromium (Cr), lithium (Li), calcium (Ca), molybdenum (Mo), titanium (Ti), tungsten (W), and copper (Cu) in consideration of adhesion with an adjacent layer, surface flatness of a stacked layer, processability, and the like, and may be formed as a single layer or multiple layers. In some embodiments, the second conductive layer may include any one of transparent conductive oxides (TCO) other than the materials described above. For example, the second conductive layer may include tungsten oxide (WxOy), titanium oxide (TiO₂), indium tin oxide (ITO), indium zinc oxide (IZO), zinc oxide (ZnO), indium tin zinc oxide (ITZO), magnesium oxide (MgO) or the like.

For example, the second conductive layer may have a structure in which titanium (Ti), copper (Cu), and an indium tin oxide (ITO) are stacked from the bottom, but is not limited thereto.

The second conductive layer may further include a capacitor electrode that overlaps the lower light blocking layer BML, and thus the aforementioned storage capacitor Cst may be formed in the overlapping area of the capacitor electrode and the lower light blocking layer BML.

A passivation layer 117 may be positioned on the second conductive layer. In some embodiments, the passivation layer 117 may be positioned in the display area DA and the non-display area NDA. In some embodiments, the passivation layer 117 may include an inorganic material such as SiO₂, SiNx, SiON, Al₂O₃, TiO₂, Ta₂O, HfO₂, ZrO₂, or the like.

A via layer 130 may be positioned on the passivation layer 117. The via layer 130 may cover the thin film transistors T1, T2, and T3 in the display area DA. In some embodiments, the via layer 130 may be a planarization layer. In some embodiments, the via layer 130 may be made of an organic material. For example, the via layer 130 may include acrylic resin, epoxy resin, imide resin, ester resin, or the like. In some embodiments, the via layer 130 may include a photosensitive organic material.

In the display area DA, a first anode electrode AE1, a second anode electrode AE2, and a third anode electrode AE3 may be positioned on the via layer 130. Each anode electrode AE1, AE2, AE3 may be connected to the source electrode SE of each transistor through a contact hole penetrating the via layer 130 and the passivation layer 117. For example, the first anode electrode AE1 may be connected to the source electrode SE of the first transistor T1 through a contact hole penetrating the via layer 130 and the passivation layer 117.

The first anode electrode AE1 may overlap the first emission area LA1 and may partially extend to the non-emission area NLA. The second anode electrode AE2 may overlap the second emission area LA2 and may partially extend to the non-emission area NLA, and the third anode electrode AE3 may overlap the third emission area LA3 and may partially extend to the non-emission area NLA.

In some embodiments, the first anode electrode AE1, the second anode electrode AE2, and the third anode electrode AE3 may be reflective electrodes. In this case, the first anode electrode AE1, the second anode electrode AE2 and the third anode electrode AE3 may be a metal layer containing metal such as Ag, Mg, Al, Pt, Pd, Au, Ni, Nd, Ir, or Cr. In an embodiment, the first anode electrode AE1, the second anode electrode AE2 and the third anode electrode AE3 may further include a metal oxide layer stacked on the metal layer. In an exemplary embodiment, the first anode electrode AE1, the second anode electrode AE2, and the third anode electrode AE3 may have a multi-layer structure, e.g., a two-layer structure of ITO/Ag, Ag/ITO, ITO/Mg, ITO/MgF or a three-layer structure of ITO/Ag/ITO.

A connection electrode CNE may be electrically connected to the second driving voltage line VSL in the non-display area NDA, and may be in direct contact with the second driving voltage line VSL. In some embodiments, although not shown, the connection electrode CNE may be disposed in the display area DA and may be electrically connected to the second driving voltage line VSL on the display area DA.

The connection pad electrode PD may be disposed in the non-display area NDA, and may be electrically connected to the first driving voltage line VDL (e.g., the first upper voltage line VDLb of the first driving voltage line VDL) of the aforementioned second conductive layer.

A pixel defining layer 150 may be positioned on the first anode electrode AE1, the second anode electrode AE2 and the third anode electrode AE3. The pixel defining layer 150 may include an opening exposing the first anode electrode AE1, an opening exposing the second anode electrode AE2 and an opening exposing the third anode electrode AE3, and may define the first emission area LA1, the second emission area LA2, the third emission area LA3 and the non-emission area NLA. That is, a region of the first anode electrode AE1 which is exposed without being covered by the pixel defining layer 150 may be the first emission area LA1. Similarly, a region of the second anode electrode AE2 which is exposed without being covered by the pixel defining layer 150 may be the second emission area LA2, and a region of the third anode electrode AE3 which is exposed without being covered by the pixel defining layer 150 may be the third emission area LA3. Further, a region where the pixel defining layer 150 is located may be the non-emission area NLA.

In some embodiments, the pixel defining layer 150 may include an organic insulating material selected from the group consisting of acrylic resin, epoxy resin, phenolic resin, polyamide resin, polyimide resin, unsaturated polyester resin, polyphenylene ether resin, polyphenylenesulfide resin and benzocyclobutene (BCB).

In some embodiments, the pixel defining layer 150 may overlap a light blocking pattern 250 to be described later. Further, in some embodiments, the pixel defining layer 150 may also overlap a bank pattern 370 to be described later.

As illustrated in FIGS. 10 and 13, a light emitting layer OL may be positioned on the first anode electrode AE1, the second anode electrode AE2, and the third anode electrode AE3.

In some embodiments, the light emitting layer OL may have a shape of a continuous film formed over the plurality of emission areas LA1, LA2, and LA3 and the non-emission area NLA. Although it is illustrated in the drawing that the light emitting layer OL is positioned only in the display area DA, the present disclosure is not limited thereto. In some other embodiments, a part of the light emitting layer OL may be further positioned in the non-display area NDA. A more detailed description of the light emitting layer OL will be given later.

A cathode electrode CE may be located on the light emitting layer OL. A part of the cathode electrode CE may be further positioned in the non-display area NDA. The cathode electrode CE may be electrically connected to the connection electrode CNE in the non-display area NDA and may be in contact with the connection electrode CNE. The driving voltage (e.g., the second driving voltage) provided to the second driving voltage line VSL may be transmitted to the cathode electrode CE via the connection electrode CNE.

In some embodiments, the cathode electrode CE may have a semi-transmissive or transmissive property. When the cathode electrode CE has a semi-transmissive property, the cathode electrode CE may include Ag, Mg, Cu, Al, Pt, Pd, Au, Ni, Nd, Ir, Cr, Li, Ca, LiF/Ca, LiF/Al, Mo, Ti or a compound or mixture thereof, such as a mixture of Ag and Mg. In addition, when the cathode electrode CE has a thickness of tens to hundreds of angstroms, the cathode electrode CE may have a semi-transmissive property.

When the cathode electrode CE has a transmissive property, the cathode electrode CE may include a transparent conductive oxide (TCO). For example, the cathode electrode CE may include tungsten oxide (WxOy), titanium oxide (TiO₂), indium tin oxide (ITO), indium zinc oxide (IZO), zinc oxide (ZnO), indium tin zinc oxide (ITZO), magnesium oxide (MgO) or the like.

In some embodiments, the cathode electrode CE may completely cover the light emitting layer OL. In some embodiments, as shown in FIG. 13, the end of the cathode electrode CE may be positioned relatively more outward than the end of the light emitting layer OL, and the end of the light emitting layer OL may be completely covered by the cathode electrode CE.

The first anode electrode AE1, the light emitting layer OL and the cathode electrode CE may constitute a first light emitting element ED1. The second anode electrode AE2, the light emitting layer OL and the cathode electrode CE may constitute a second light emitting element ED2. The third anode electrode AE3, the light emitting layer OL and the cathode electrode CE may constitute a third light emitting element ED3. Each of the first light emitting element ED1, the second light emitting element ED2, and the third light emitting element ED3 may emit an emission light LE.

As illustrated in FIG. 11, the emission light LE ultimately emitted from the light emitting layer OL may be a mixed light in which a first component LE1 and a second component LE2 are mixed. Each of the first component LE1 and the second component LE2 in the emission light LE may have a peak wavelength within a range of 440 nm or more and less than 480 nm. That is, the emission light LE may be blue light.

As illustrated in FIG. 11, in some embodiments, the light emitting layer OL may have a structure in which a plurality of light emitting layers overlap, e.g., a tandem structure. For example, the light emitting layer OL may include a first stack ST1 including a first light emitting layer EML1, a second stack ST2 positioned on the first stack ST1 and including a second light emitting layer EML2, a third stack ST3 positioned on the second stack ST2 and including a third light emitting layer EML3, a first charge generation layer CGL1 positioned between the first stack ST1 and the second stack ST2, and a second charge generation layer CGL2 positioned between the second stack ST2 and the third stack ST3. The first stack ST1, the second stack ST2, and the third stack ST3 may be disposed to overlap each other.

The first light emitting layer EML1, the second light emitting layer EML2, and the third light emitting layer EML3 may be disposed to overlap each other.

In some embodiments, all the first light emitting layer EML1, the second light emitting layer EML2, and the third light emitting layer EML3 may emit light of the first color, e.g., blue light. For example, each of the first light emitting layer EML1, the second light emitting layer EML2, and the third light emitting layer EML3 may be a blue light emitting layer, and may include an organic material.

In some embodiments, at least one of the first light emitting layer EML1, the second light emitting layer EML2, or the third light emitting layer EML3 may emit a first blue light having a first peak wavelength, and at least another one of the first light emitting layer EML1, the second light emitting layer EML2, or the third light emitting layer EML3 may emit a second blue light having a second peak wavelength different from the first peak wavelength. For example, any one of the first light emitting layer EML1, the second light emitting layer EML2, and the third light emitting layer EML3 may emit the first blue light having the first peak wavelength, and the other two of the first light emitting layer EML1, the second light emitting layer EML2, and the third light emitting layer EML3 may emit the second blue light having the second peak wavelength. That is, the emission light LE ultimately emitted from the light emitting layer OL may be a mixed light in which the first component LE1 and the second component LE2 are mixed, and the first component LE1 may be the first blue light having the first peak wavelength, and the second component LE2 may be the second blue light having the second peak wavelength.

In some embodiments, one of the first peak wavelength and the second peak wavelength may be in a range of 440 nm or more and less than 460 nm, and the other one thereof may be in a range of 460 nm or more and 480 nm or less. However, the range of the first peak wavelength and the range of the second peak wavelength are not limited thereto. For example, both the range of the first peak wavelength and the range of the second peak wavelength may include 460 nm. In some embodiments, one of the first blue light and the second blue light may be deep blue color, and the other one thereof may be sky blue color.

In accordance with some embodiments, the emission light LE emitted from the light emitting layer OL may be blue light, and may include a long wavelength component and a short wavelength component. Therefore, ultimately, the light emitting layer OL may emit blue light having an emission peak in a broader wavelength range as the emission light LE. Accordingly, there is an advantage in that color visibility may be improved at a side viewing angle compared to a conventional light emitting element emitting blue light having a sharp emission peak.

In some embodiments, each of the first light emitting layer EML1, the second light emitting layer EML2, and the third light emitting layer EML3 may include a host and a dopant. A material of the host is not particularly limited as long as it is generally used. For example, tris(8-hydroxyquinolinato)aluminum (Alq3), 4,4′-bis(N-carbazolyl)-1,1′-biphenyl (CBP), poly(n-vinylcarbazole) (PVK), 9,10-di(naphthalene-2-yl)anthracene (ADN), 4,4′,4″-Tris(carbazol-9-yl)-triphenylamine (TCTA), 1,3,5-tris(N-phenylbenzimidazole-2-yl)benzene (TPBi), 3-tert-butyl-9,10-di(naphth-2-yl)anthracene (TBADN), distyrylarylene (DSA), 4,4′-bis(9-carbazolyl)-2,2′-dimethyl-biphenyl (CDBP), or 2-methyl-9,10-bis(naphthalen-2-yl)anthracene (MADN), and the like may be used.

Each of the first light emitting layer EML1, the second light emitting layer EML2, and the third light emitting layer EML3 emitting blue light may include, e.g., a fluorescent material including any one selected from the group consisting of spiro-DPVBi, spiro-6P, distyryl-benzene (DSB), distyryl-arylene (DSA), polyfluorene (PFO)-based polymer, and poly(p-phenylene vinylene) (PPV)-based polymer. As another example, a phosphorescent material containing an organometallic complex such as (4,6-F2ppy)2Irpic may be included.

As described above, at least one of the first light emitting layer EML1, the second light emitting layer EML2, or the third light emitting layer EML3 emits blue light of a wavelength range different from that of at least another one of the first light emitting layer EML1, the second light emitting layer EML2, or the third light emitting layer EML3. In order to emit blue light in different wavelength ranges, the first light emitting layer EML1, the second light emitting layer EML2, and the third light emitting layer EML3 may include the same material, and a resonance distance may be adjusted. In an embodiment, in order to emit blue light in different wavelength ranges, at least one of the first light emitting layer EML1, the second light emitting layer EML2, and the third light emitting layer EML3, and at least another one of the first light emitting layer EML1, the second light emitting layer EML2, and the third light emitting layer EML3 may include different materials from each other.

However, the present disclosure is not limited thereto, and the first light emitting layer EML1, the second light emitting layer EML2, and the third light emitting layer EML3 may emit blue light having a peak wavelength within a range of 440 nm to 480 nm, and may be made of the same material.

In an embodiment, at least any one of the first light emitting layer EML1, the second light emitting layer EML2, or the third light emitting layer EML3 may emit the first blue light having the first peak wavelength, another one of the first light emitting layer EML1, the second light emitting layer EML2, and the third light emitting layer EML3 may emit the second blue light having the second peak wavelength different from the first peak wavelength, and the other one of the first light emitting layer EML1, the second light emitting layer EML2, and the third light emitting layer EML3 may emit third blue light having a third peak wavelength different from the first peak wavelength and the second peak wavelength. In some other embodiments, any one of the first peak wavelength, the second peak wavelength, and the third peak wavelength may be within a range of 440 nm or more and less than 460 nm. Another one of the first peak wavelength, the second peak wavelength, and the third peak wavelength may be within a range of 460 nm or more and less than 470 nm, and the other one of the first peak wavelength, the second peak wavelength, and the third peak wavelength may be within a range of 470 nm or more and 480 nm or less.

In accordance with some other embodiments, the emission light LE emitted from the light emitting layer OL is blue light, and includes a long wavelength component, an intermediate wavelength component, and a short wavelength component. Therefore, ultimately, the light emitting layer OL may emit blue light having an emission peak in a broader wavelength range as the emission light LE, thereby improving the color visibility at a side viewing angle.

In accordance with the above-described embodiments, compared to the conventional light emitting element that does not adopt a tandem structure, i.e., a structure in which a plurality of light emitting layers are stacked, it is advantageous in that the light efficiency increases and the lifespan of the display device increases.

In some other embodiments, at least one of the first light emitting layer EML1, the second light emitting layer EML2, or the third light emitting layer EML3 may emit light of the third color, e.g., blue light, and at least another one of the first light emitting layer EML1, the second light emitting layer EML2, or the third light emitting layer EML3 may emit light of the second color, e.g., green light. In some other embodiments, the range of the peak wavelength of blue light emitted by at least one of the first light emitting layer EML1, the second light emitting layer EML2, or the third light emitting layer EML3 may be within a range of 440 nm or more and 480 nm or less, or 460 nm or more and 480 nm or less. The green light emitted from at least one of the first light emitting layer EML1, the second light emitting layer EML2, or the third light emitting layer EML3 may have a peak wavelength within a range of 510 nm to 550 nm.

For example, any one of the first light emitting layer EML1, the second light emitting layer EML2, and the third light emitting layer EML3 may be a green light emitting layer emitting green light, and the other two among the first light emitting layer EML1, the second light emitting layer EML2, and the third light emitting layer EML3 may be blue light emitting layers emitting blue light. When the other two among the first light emitting layer EML1, the second light emitting layer EML2, and the third light emitting layer EML3 are the blue light emitting layers, the peak wavelength ranges of the blue light emitted by the two blue light emitting layers may be the same, or may be different from each other.

In accordance with some other embodiments, the emission light LE emitted from the light emitting layer OL may be a mixed light in which the first component LE1 that is blue light and the second component LE2 that is green light are mixed. For example, when the first component LE1 is deep blue light and the second component LE2 is green light, the emission light LE may be sky blue light. Similarly to the above-described embodiments, the emission light LE emitted from the light emitting layer OL, which is a mixture of blue light and green light, includes a long wavelength component and a short wavelength component. Therefore, ultimately, the light emitting layer OL may emit blue light having an emission peak in a broader wavelength range as the emission light LE, thereby improving the color visibility at a side viewing angle. In addition, since the second component LE2 of the emission light LE is green light, the green light component of the light provided from the display device 1 to the outside may be supplemented, thereby improving the color reproducibility of the display device 1.

In some embodiments, the green light emitting layer among the first light emitting layer EML1, the second light emitting layer EML2, and the third light emitting layer EML3 may include a host and a dopant. A material of the host including the green light emitting layer is not particularly limited as long as it is generally used. For example, tris(8-hydroxyquinolinato)aluminum (Alq3), 4,4′-bis(N-carbazolyl)-1,1′-biphenyl (CBP), poly(n-vinylcarbazole) (PVK), 9,10-di(naphthalene-2-yl)anthracene (ADN), 4,4′,4″-Tris(carbazol-9-yl)-triphenylamine (TCTA), 1,3,5-tris(N-phenylbenzimidazole-2-yl)benzene (TPBi), 3-tert-butyl-9,10-di(naphth-2-yl)anthracene (TBADN), distyrylarylene (DSA), 4,4′-bis(9-carbazolyl)-2,2′-dimethyl-biphenyl (CDBP), or 2-methyl-9,10-bis(naphthalen-2-yl)anthracene (MADN), and the like may be used.

The dopant included in the green light emitting layer may include a fluorescent material containing, for example, tris(8-hydroxyquinolinato)aluminum(III) (Alq3), or a phosphorescent material such as fac tris(2-phenylpyridine)iridium (Ir(ppy)3), bis(2-phenylpyridine)(acetylacetonate)iridium(III) (Ir(ppy)2(acac)), and 2-phenyl-4-methyl-pyridine iridium (Ir(mpyp)3).

The first charge generation layer CGL1 may be positioned between the first stack ST1 and the second stack ST2. The first charge generation layer CGL1 may serve to allow charges to be injected into each light emitting layer. The first charge generation layer CGL1 may serve to control charge balance between the first stack ST1 and the second stack ST2. The first charge generation layer CGL1 may include an n-type charge generation layer CGL11 and a p-type charge generation layer CGL12. The p-type charge generation layer CGL12 may be disposed on the n-type charge generation layer CGL11, and between the n-type charge generation layer CGL11 and the second stack ST2.

The first charge generation layer CGL1 may have a structure in which the n-type charge generation layer CGL11 and the p-type charge generation layer CGL12 are in contact with each other. The n-type charge generation layer CGL11 is disposed closer to the anode electrodes AE1, AE2, and AE3 between the anode electrodes AE1, AE2, and AE3 and the cathode electrode CE. The p-type charge generation layer CGL12 is disposed closer to the cathode electrode CE between the anode electrodes AE1, AE2, and AE3 and the cathode electrode CE. The n-type charge generation layer CGL11 supplies electrons to the first light emitting layer EML1 adjacent to the anode electrodes AE1, AE2, and AE3, and the p-type charge generation layer CGL12 supplies holes to the second light emitting layer EML2 included in the second stack ST2. The first charge generation layer CGL1 is disposed between the first stack ST1 and the second stack ST2 to provide charges to each light emitting layer, thereby increasing luminous efficiency and decreasing a driving voltage.

The first stack ST1 may be positioned on the first anode electrode AE1, the second anode electrode AE2, and the third anode electrode AE3, and may further include a first hole transport layer HTL1, a first electron block layer BIL1, and a first electron transport layer ETL1.

The first hole transport layer HTL1 may be disposed on the first anode electrode AE1, the second anode electrode AE2, and the third anode electrode AE3. The first hole transport layer HTL1 serves to facilitate the transport of holes and may include a hole transport material. The hole transport material may include a carbazole-based derivative such as N-phenylcarbazole and polyvinylcarbazole, a fluorene-based derivative, a triphenylamine-based derivative such as N,N′-bis(3-methylphenyl)-N,N′-diphenyl)-[1,1-biphenyl]-4,4′-diamine (TPD) and 4,4′,4″-tris(N-carbazolyl)triphenylamine (TCTA), N,N′-di(1-naphthyl)-N,N′-diphenylbenzidine (NPB), 4,4′-Cyclohexylidene bis[N,N-bis(4-methylphenyl)benzenamine](TAPC), or the like, but the present disclosure is not limited thereto.

The first electron block layer BIL1 may be positioned on the first hole transport layer HTL1, and between the first hole transport layer HTL1 and the first light emitting layer EML1. The first electron block layer BIL1 may include a hole transport material and a metal or metal compound to prevent electrons generated in the first light emitting layer EML1 from moving into the first hole transport layer HTL1. In some embodiments, the first hole transport layer HTL1 and the first electron block layer BIL1 described above may be formed as a single layer in which respective materials are mixed.

The first electron transport layer ETL1 may be positioned on the first light emitting layer EML1, and between the first charge generation layer CGL1 and the first light emitting layer EML1. In some embodiments, the first electron transport layer ETL1 may include an electron transport material such as tris(8-hydroxyquinolinato)aluminum (Alq3), 1,3,5-tri(1-phenyl-1H-benzo[d]imidazol-2-yl)phenyl (TPBi), 2,9-dimethyl-4,7-diphenyl-1,10-phenanthroline (BCP), (4,7-diphenyl-1,10-phenanthroline (Bphen), 3-(4-Biphenylyl)-4-phenyl-5-tert-butylphenyl-1,2,4-triazole (TAZ), 4-(Naphthalen-1-yl)-3,5-diphenyl-4H-1,2,4-triazole (NTAZ), 2-(4-Biphenylyl)-5-(4-tert-butylphenyl)-1,3,4-oxadiazole (tBu-PBD), bis(2-methyl-8-quinolinolato-N1,O8)-(1,1′-Biphenyl-4-olato)aluminum (BAlq), berylliumbis(benzoquinolin-10-olate (Bebq2), 9,10-di(naphthalene-2-yl)anthracene (ADN), and a mixture thereof. However, the present disclosure is not limited to the type of the electron transport material. The second stack ST2 may be positioned on the first charge generation layer CGL1, and further include a second hole transport layer HTL2, a second electron block layer BIL2, and a second electron transport layer ETL2.

The second hole transport layer HTL2 may be positioned on the first charge generation layer CGL1. The second hole transport layer HTL2 may be made of the same material as the first hole transport layer HTL1, or may include one or more materials selected from examples of materials included in the first hole transport layer HTL1. The second hole transport layer HTL2 may be formed as a single layer or a plurality of layers.

The second electron block layer BIL2 may be positioned on the second hole transport layer HTL2, and between the second hole transport layer HTL2 and the second light emitting layer EML2. The second electron block layer BIL2 may be formed of the same material and the same structure as the first electron block layer BIL1, or may include one or more materials selected from examples of materials included in the first electron block layer BILL.

The second electron transport layer ETL2 may be positioned on the second light emitting layer EML2, and between the second charge generation layer CGL2 and the second light emitting layer EML2. The second electron transport layer ETL2 may be formed of the same material and the same structure as the first electron transport layer ETL1, or may include one or more materials selected from examples of materials included in the first electron transport layer ETL1. The second electron transport layer ETL2 may be formed as a single layer or a plurality of layers.

The second charge generation layer CGL2 may be positioned on the second stack ST2 and between the second stack ST2 and the third stack ST3.

The second charge generation layer CGL2 may have the same structure as the first charge generation layer CGL1 described above. For example, the second charge generation layer CGL2 may include an n-type charge generation layer CGL21 disposed closer to the second stack ST2 and a p-type charge generation layer CGL22 disposed closer to the cathode electrode CE. The p-type charge generation layer CGL22 may be disposed on the n-type charge generation layer CGL21.

The second charge generation layer CGL2 may have a structure in which the n-type charge generation layer CGL21 and the p-type charge generation layer CGL22 are in contact with each other. The first charge generation layer CGL1 and the second charge generation layer CGL2 may be made of different materials, or may be made of the same material.

The third stack ST3 may be positioned on the second charge generation layer CGL2, and may further include a third hole transport layer HTL3 and a third electron transport layer ETL3.

The third hole transport layer HTL3 may be positioned on the second charge generation layer CGL2. The third hole transport layer HTL3 may be made of the same material as the first hole transport layer HTL1, or may include one or more materials selected from examples of materials included in the first hole transport layer HTL1. The third hole transport layer HTL3 may be formed as a single layer or a plurality of layers. When the third hole transport layer HTL3 is formed as a plurality of layers, each layer may include a different material.

The third electron transport layer ETL3 may be positioned on the third light emitting layer EML3, and between the cathode electrode CE and the third light emitting layer EML3. The third electron transport layer ETL3 may be formed of the same material and the same structure as the first electron transport layer ETL1, or may include one or more materials selected from examples of materials included in the first electron transport layer ETL1. The third electron transport layer ETL3 may be formed as a single layer or a plurality of layers. When the third electron transport layer ETL3 is formed as a plurality of layers, each layer may include a different material.

Although not shown in the drawings, a hole injection layer may be further positioned at least one of: between the first stack ST1 and the first anode electrode AE1, between the second anode electrode AE2 and the third anode electrode AE3, between the second stack ST2 and the first charge generation layer CGL1, or between the third stack ST3 and the second charge generation layer CGL2. The hole injection layer may serve to allow holes to be more smoothly injected into the first light emitting layer EML1, the second light emitting layer EML2, and the third light emitting layer EML3. In some embodiments, the hole injection layer may be made of one or materials selected from the group consisting of copper phthalocyanine (CuPc), poly(3,4)-ethylenedioxythiophene (PEDOT), polyaniline (PANI), and N,N-dinaphthyl-N,N′-diphenyl benzidine (NPD), but the present disclosure is not limited thereto. In some embodiments, the hole injection layer may be positioned between the first stack ST1 and the first anode electrode AE1, between the second anode electrode AE2 and the third anode electrode AE3, between the second stack ST2 and the first charge generation layer CGL1, and between the third stack ST3 and the second charge generation layer CGL2.

Although not shown in the drawings, an electron injection layer may be further positioned at least one of: between the third electron transport layer ETL3 and the cathode electrode CE, between the second charge generation layer CGL2 and the second stack ST2, or between the first charge generation layer CGL1 and the first stack ST1. The electron injection layer serves to facilitate electron injection, and may be made of tris(8-hydroxyquinolino)aluminum (Alq3), PBD, TAZ, spiro-PBD, BAlq, or SAlq, but the present disclosure is not limited thereto. Further, the electron injection layer may be a metal halide compound, and may include one or more materials selected from the group consisting of MgF₂, LiF, NaF, KF, RbF, CsF, FrF, LiI, NaI, KI, RbI, CsI, FrI and CaF₂, but the present disclosure is not limited thereto. Further, the electron injection layer may include a lanthanum-based material such as Yb, Sm, Eu, or the like. In an embodiment, the electron injection layer may include both the metal halide material and the lanthanum-based material, such as RbI:Yb, KI:Yb, or the like. When the electron injection layer includes both the metal halide material and the lanthanum-based material, the electron injection layer may be formed by co-deposition of the metal halide material and the lanthanum-based material. In some embodiments, the electron injection layer may be positioned between the third electron transport layer ETL3 and the cathode electrode CE, between the second charge generation layer CGL2 and the second stack ST2, and between the first charge generation layer CGL1 and the first stack ST1.

The light emitting layer OL may have a modified structure in addition to the above-described structure. For example, the light emitting layer OL may be deformed to a light emitting layer OLa shown in FIG. 12. Unlike the structure shown in FIG. 11, the light emitting layer OLa shown in FIG. 12 may further include a fourth stack ST4 on the third stack ST3, and may further include a third charge generation layer CGL3 positioned between the third stack ST3 and the fourth stack ST4.

The fourth stack ST4 may include a fourth light emitting layer EML4, and may further include a fourth hole transport layer HTL4, and a fourth electron transport layer ETL4.

Each of the first light emitting layer EML1, the second light emitting layer EML2, the third light emitting layer EML3, and the fourth light emitting layer EML4 included in the light emitting layer OL may emit light of the third color, e.g., blue light. At least one of the first light emitting layer EML1, the second light emitting layer EML2, the third light emitting layer EML3, or the fourth light emitting layer EML4, and at least another one of the first light emitting layer EML1, the second light emitting layer EML2, the third light emitting layer EML3, or the fourth light emitting layer EML4 may emit blue light in different peak wavelength ranges.

In an embodiment, at least one of the first light emitting layer EML1, the second light emitting layer EML2, the third light emitting layer EML3, or the fourth light emitting layer EML4 may emit green light, and at least another one of the first light emitting layer EML1, the second light emitting layer EML2, the third light emitting layer EML3, or the fourth light emitting layer EML4 may emit blue light. For example, any one of the first light emitting layer EML1, the second light emitting layer EML2, the third light emitting layer EML3, and the fourth light emitting layer EML4 may be a green light emitting layer, and the other three light emitting layers may be blue light emitting layers.

In an embodiment, the fourth light emitting layer EML4 may be a green light emitting layer, and all the first light emitting layer EML1, the second light emitting layer EML2, and the third light emitting layer EML3 may be blue light emitting layers.

The fourth hole transport layer HTL4 may be positioned on the second charge generation layer CGL2. The fourth hole transport layer HTL4 may be made of the same material as the first hole transport layer HTL1, or may include one or more materials selected from examples of materials included in the first hole transport layer HTL1. The fourth hole transport layer HTL4 may be formed as a single layer or a plurality of layers. When the fourth hole transport layer HTL4 is formed of a plurality of layers, each layer may include a different material.

A third electron block layer BIL3 may be positioned on the third hole transport layer HTL3, and may be positioned between the third hole transport layer HTL3 and the third light emitting layer EML3. The third electron block layer BIL3 may be formed of the same material and the same structure as the first electron block layer BIL1, or may include one or more materials selected from examples of materials included in the first electron block layer BILL. In some other embodiments, the third electron block layer BIL3 may be omitted.

The fourth electron transport layer ETL4 may be positioned on the fourth light emitting layer EML4, and between the fourth light emitting layer EML4 and the cathode electrode CE. The fourth electron transport layer ETL4 may be formed of the same material and the same structure as the first electron transport layer ETL1, or may include one or more materials selected from examples of materials included in the first electron transport layer ETL1. The fourth electron transport layer ETL4 may be formed as a single layer or a plurality of layers. When the fourth electron transport layer ETL4 is formed of a plurality of layers, each layer may include a different material.

The third charge generation layer CGL3 may have the same structure as the first charge generation layer CGL1 described above. For example, the third charge generation layer CGL3 may include an n-type charge generation layer CGL31 disposed closer to the second stack ST2 and a p-type charge generation layer CGL32 disposed closer to the cathode electrode CE. The p-type charge generation layer CGL32 may be disposed on the n-type charge generation layer CGL31.

Although not shown in the drawing, the electron injection layer may be further positioned between the fourth stack ST4 and the third charge generation layer CGL3. Further, the hole injection layer may be further positioned between the fourth stack ST4 and the second charge generation layer CGL2.

In some embodiments, both the light emitting layer OL shown in FIG. 11 and the light emitting layer OLa shown in FIG. 12 may not include a red light emitting layer in common, and thus may not emit light of the first color, e.g., red light. That is, the emission light LE may not include a light component having a peak wavelength of 610 nm to about 650 nm, and the emission light LE may include only a light component having a peak wavelength of 440 nm to 550 nm.

As illustrated in FIG. 13, the dam member DM may be positioned on the passivation layer 117 in the non-display area NDA.

The dam member DM may be positioned relatively more outward than the second driving voltage line VSL. In other words, as illustrated in FIG. 13, the second driving voltage line VSL may be positioned between the dam member DM and the display area DA.

In some embodiments, the dam member DM may include a plurality of dams. For example, the dam member DM may include a first dam D1 and a second dam D2.

The first dam D1 may partially overlap the second driving voltage line VSL, and may be spaced apart from the via layer 130 with the second driving voltage line VSL interposed therebetween. In some embodiments, the first dam D1 may include a first lower dam pattern D11 positioned on the passivation layer 117, and a first upper dam pattern D12 positioned on the first lower dam pattern D11.

The second dam D2 may be positioned more outward than the first dam D1, and may be spaced apart from the first dam D1. In some embodiments, the second dam D2 may include a second lower dam pattern D21 positioned on the passivation layer 117, and a second upper dam pattern D22 positioned on the second lower dam pattern D21.

In some embodiments, the first lower dam pattern D11 and the second lower dam pattern D21 may be made of the same material as the via layer 130 and may be formed simultaneously with the via layer 130.

In some embodiments, the first upper dam pattern D12 and the second upper dam pattern D22 may be made of the same material as the pixel defining layer 150 and may be formed simultaneously with the pixel defining layer 150.

In some embodiments, the heights of the first dam D1 and the second dam D2 may be different from each other. For example, the height of the second dam D2 may be higher than the height of the first dam D1. That is, as the distance from the display area DA increases, the height of the dam included in the dam member DM may gradually increase. Accordingly, it is possible to effectively prevent the organic material from overflowing in a process of forming an organic layer 173 included in an encapsulation layer 170 to be described later.

As illustrated in FIGS. 10 and 13, a capping layer 160 may be positioned on the cathode electrode CE. The capping layer 160 may be commonly disposed in the first emission area LA1, the second emission area LA2, the third emission area LA3, and the non-emission area NLA, and may improve viewing angle characteristics and increase external luminous efficiency.

The capping layer 160 may include at least one of an inorganic material or an organic material having a light transmissive property. That is, the capping layer 160 may be formed of an inorganic layer, an organic layer, or an organic layer including inorganic particles. For example, the capping layer 160 may include a triamine derivative, a carbazole biphenyl derivative, an arylenediamine derivative, an aluminum quinolium complex (Alq3), or the like.

Further, the capping layer 160 may be made of a mixture of a high refractive material and a low refractive material. In an embodiment, the capping layer 160 may include two layers having different refractive indices, e.g., a high refractive layer and a low refractive layer.

In some embodiments, the capping layer 160 may completely cover the cathode electrode CE. In some embodiments, as shown in FIG. 13, the end of the capping layer 160 may be positioned relatively more outward than the end of the cathode electrode CE, and the end of the cathode electrode CE may be completely covered by the capping layer 160.

The encapsulation layer 170 may be disposed on the capping layer 160. The encapsulation layer 170 protects components positioned under the encapsulation layer 170, such as the light emitting elements ED1, ED2, and ED3, from external foreign substances such as moisture. The encapsulation layer 170 is commonly disposed in the first emission area LA1, the second emission area LA2, the third emission area LA3, and the non-emission area NLA. In some embodiments, the encapsulation layer 170 may directly cover the cathode electrode CE. In some embodiments, the capping layer 160 covering the cathode electrode CE may be further disposed between the encapsulation layer 170 and the cathode electrode CE. In this case, the encapsulation layer 170 may directly cover the capping layer 160. The encapsulation layer 170 may be a thin film encapsulation layer.

In some embodiments, the encapsulation layer 170 may include a lower inorganic layer 171, the organic layer 173, and an upper inorganic layer 175 that are sequentially stacked on the capping layer 160.

In some embodiments, the lower inorganic layer 171 may cover the first light emitting element ED1, the second light emitting element ED2, and the third light emitting element ED3 in the display area DA. The lower inorganic layer 171 may cover the dam member DM in the non-display area NDA, and may extend to the outside of the dam member DM.

In some embodiments, the lower inorganic layer 171 may completely cover the capping layer 160. In some embodiments, the end of the lower inorganic layer 171 may be positioned relatively more outward than the end of the capping layer 160, and the end of the capping layer 160 may be completely covered by the lower inorganic layer 171.

The lower inorganic layer 171 may include a plurality of stacked layers. The organic layer 173 may be positioned on the lower inorganic layer 171. The organic layer 173 may cover the first light emitting element ED1, the second light emitting element ED2, and the third light emitting element ED3 in the display area DA. In some embodiments, a part of the organic layer 173 may be positioned in the non-display area NDA, and may not be positioned more outward than the dam member DM. Although it is illustrated that a part of the organic layer 173 is positioned more inward than the first dam D1, the present disclosure is not limited thereto. In some other embodiments, a part of the organic layer 173 may be accommodated in the space between the first dam D1 and the second dam D2, and the end of the organic layer 173 may be positioned in the area between the first dam D1 and the second dam D2.

The upper inorganic layer 175 may be positioned on the organic layer 173. The upper inorganic layer 175 may cover the organic layer 173. In some embodiments, the upper inorganic layer 175 may be in direct contact with the lower inorganic layer 171 in the non-display area NDA to form an inorganic-inorganic junction. In some embodiments, the end of the upper inorganic layer 175 and the end of the lower inorganic layer 171 may be substantially aligned. The upper inorganic layer 175 may include a plurality of stacked layers.

In some embodiments, each of the lower inorganic layer 171 and the upper inorganic layer 175 may be formed of silicon nitride, aluminum nitride, zirconium nitride, titanium nitride, hafnium nitride, tantalum nitride, silicon oxide, aluminum oxide, titanium oxide, tin oxide, cerium oxide, silicon oxynitride (SiON), lithium fluoride or the like.

In some embodiments, the organic layer 173 may be formed of acrylic resin, methacrylic resin, polyisoprene, vinyl resin, epoxy resin, urethane resin, cellulose resin, perylene resin or the like.

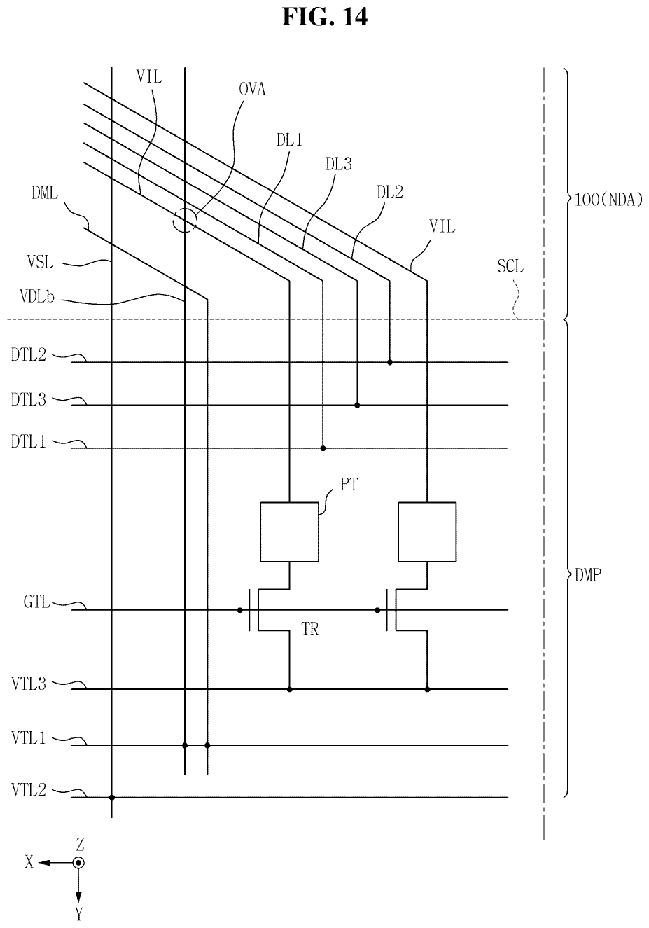

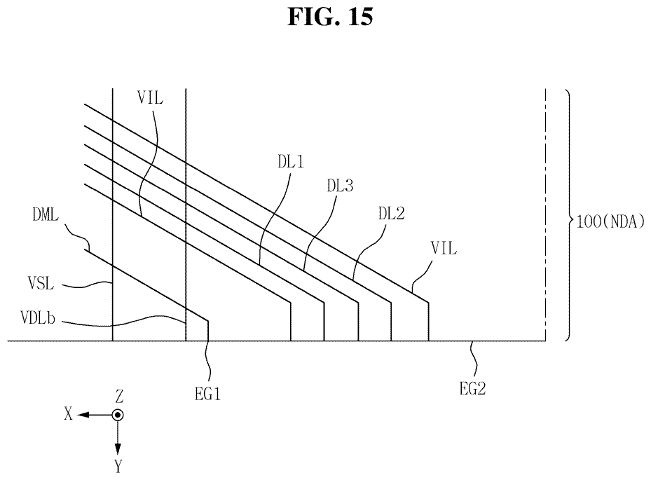

Hereinafter, the aforementioned dummy line DML will be described in more detail with reference to FIGS. 14 and 15.

FIG. 14 is a plan view of the dummy line DML and peripheral components in a base substrate including the display panel 100 according to an embodiment.

First, the display panel 100 of the display device 1 may be manufactured by cutting (or separating) a base substrate (or mother substrate) into cell units. For example, the plurality of display panels 100 may be manufactured in cell units by cutting the base substrate along scribing lines SCL. FIG. 14 is a diagram showing a base substrate before a scribing process. With respect to the scribing line SCL of FIG. 14, the upper portion corresponds to the display panel 100 and the lower portion corresponds to a dummy panel DMP that is removed after the scribing process. The display panel 100 may include the display area DA and the non-display area NDA described above. In other words, the portion above the scribing line SCL corresponds to the display panel 100 of the display device described above.

The first upper voltage line VDLb may be disposed on the display panel 100 and the dummy panel DMP.

The second driving voltage line VSL may be disposed on the display panel 100 and the dummy panel DMP.

Data lines DL1, DL2, and DL3 may be disposed on the display panel 100 and the dummy panel DMP. The data lines DL1, DL2, and DL3 may overlap the first upper voltage line VDLb and the second driving voltage line VSL on the display panel 100.

The initialization voltage lines VIL may be disposed on the display panel 100 and the dummy panel DMP. The initialization voltage lines VIL may overlap the first upper voltage line VDLb and the second driving voltage line VSL on the display panel 100.

The dummy line DML may be disposed on the display panel 100 and the dummy panel DMP. The dummy line DML may overlap the first upper voltage line VDLb and the second driving voltage line VSL on the display panel 100. The dummy line DML may have a bent shape.

A first voltage transmission line VTL1 may be disposed on the dummy panel DMP. The first voltage transmission line VTL1 may transmit the first driving voltage. The first voltage transmission line VTL1 may overlap the first upper voltage line VDLb, the second driving voltage line VSL, and the dummy line DML on the dummy panel DMP. The first voltage transmission line VTL1 and the first upper voltage line VDLb may be connected to each other on the dummy panel DMP. For example, the first voltage transmission line VTL1 and the first upper voltage line VDLb may be connected to each other at an intersection point of the first voltage transmission line VTL1 and the first upper voltage line VDLb. In some embodiments, the first voltage transmission line VTL1 and the dummy line DML may be connected to each other on the dummy panel DMP. For example, the first voltage transmission line VTL1 and the dummy line DML may be connected to each other at an intersection point of the first voltage transmission line VTL1 and the dummy line DML. As another example, the first voltage transmission line VTL1 may not be connected to the dummy line DML.

A second voltage transmission line VTL2 may be disposed on the dummy panel DMP. The second voltage transmission line VTL2 may transmit the second driving voltage. The second voltage transmission line VTL2 may overlap the second driving voltage line VSL on the dummy panel DMP. The second voltage transmission line VTL2 and the second driving voltage line VSL may be connected to each other on the dummy panel DMP. For example, the second voltage transmission line VTL2 and the second driving voltage line VSL may be connected to each other at an intersection point of the second voltage transmission line VTL2 and the second driving voltage line VSL.

A third voltage transmission line VTL3 may be disposed on the dummy panel DMP. The third voltage transmission line VTL3 may transmit an initialization voltage. The third voltage transmission line VTL3 may overlap the first upper voltage line VDLb, the second driving voltage line VSL, and the dummy line DML on the dummy panel DMP.

A gate transmission line GTL may be disposed on the dummy panel DMP. The gate transmission line GTL may overlap the first upper voltage line VDLb, the second driving voltage line VSL, and the dummy line DML on the dummy panel DMP.

A test transistor TR may be disposed on the dummy panel DMP. The gate electrode of the test transistor TR may be connected to the gate transmission line GTL, the source electrode thereof may be connected to the third voltage transmission line VTL3, and the drain electrode thereof may be connected to the initialization voltage line VIL via an inspection pad electrode PT. The test transistor TR may be turned on according to a gate signal from the gate transmission line GTL to connect the inspection pad electrode PT and the third voltage transmission line VTL3 to each other.

A first data transmission line DTL1 may be disposed on the dummy panel DMP. The first data transmission line DTL1 may overlap the first upper voltage line VDLb, the second driving voltage line VSL, the initialization voltage line VIL, the dummy line DML, and the first data line DL1 on the dummy panel DMP. The first data transmission line DTL1 and the first data line DL1 may be connected to each other on the dummy panel DMP. For example, the first data transmission line DTL1 and the first data line DL1 may be connected to each other at an intersection point of the first data transmission line DTL1 and the first data line DL1. For example, the first data transmission line DTL1 may transmit a first data voltage necessary for light emission of a pixel that provides red light.

A second data transmission line DTL2 may be disposed on the dummy panel DMP. The second data transmission line DTL2 may overlap the first upper voltage line VDLb, the second driving voltage line VSL, the initialization voltage line VIL, the dummy line DML, the first data line DL1, the second data line DL2, and the third data line DL3 on the dummy panel DMP. The second data transmission line DTL2 and the second data line DL2 may be connected to each other on the dummy panel DMP. For example, the second data transmission line DTL2 and the second data line DL2 may be connected to each other at an intersection point of the second data transmission line DTL2 and the second data line DL2. For example, the second data transmission line DTL2 may transmit a second data voltage necessary for light emission of a pixel that provides green light.

A third data transmission line DTL3 may be disposed on the dummy panel DMP. The third data transmission line DTL3 may overlap the first upper voltage line VDLb, the second driving voltage line VSL, the initialization voltage line VIL, the dummy line DML, the first data line DL1, and the third data line DL3 on the dummy panel DMP. The third data transmission line DTL3 and the third data line DL3 may be connected to each other on the dummy panel DMP. For example, the third data transmission line DTL3 and the third data line DL3 may be connected to each other at an intersection point of the third data transmission line DTL3 and the third data line DL3. For example, the third data transmission line DTL3 may transmit a third data voltage necessary for light emission of a pixel that provides blue light.

According to some embodiments, the first data line DL1 may include a signal line disposed in the display area DA and a link line (or connection line) disposed in a fan-out region of the non-display area NDA. Here, the signal line of the first data line DL1 may be connected to the link line of the first data line DL1. The first data line DL1 shown in FIG. 14 may be, for example, a link line of the first data line DL1. Further, the second and third data lines may also include a signal line and a link line similarly to the first data line described above. The second data line DL2 shown in FIG. 14 may be, for example, a link line of the second data line DL2. Further, the third data line DL3 shown in FIG. 14 may be, for example, a link line of the third data line DL3.

Static electricity may be generated while various processes are performed on the base substrate, and the static electricity may be discharged to the outside through the turned-on test transistor TR. For example, when static electricity is generated in the initialization voltage line VIL during a process, the static electricity in the initialization voltage line VIL may be discharged to the third voltage transmission line VTL3 through the turned-on test transistor TR.

In addition, during an inspection process, the current of each pixel is detected by the inspection pad electrode PT and the initialization voltage line VIL, and the detected current may be measured to check whether each pixel is defective or not. For the inspection, the aforementioned gate signal, first driving voltage, second driving voltage, initialization voltage, first data voltage, second data voltage, and third data voltage may be applied to the gate transmission line GTL, the first voltage transmission line VTL1, the second voltage transmission line VTL2, the third voltage transmission line VTL3, the first data transmission line DTL1, the second data transmission line DTL2 and the third data transmission line DTL3, respectively.

When static electricity flows into the first upper voltage line VDLb, charges may accumulate in the first upper voltage line VDLb due to the static electricity. In particular, the charges of the first upper voltage line VDLb may be collectively accumulated in the overlapping area OVA of the first upper voltage line VDLb and the initialization voltage line VIL. For example, a large amount of charges may be accumulated in the overlapping area OVA of the first upper voltage line VDLb and the initialization voltage line VIL by a parasitic capacitance formed in the overlapping area OVA. In this case, the insulating layer (e.g., the buffer layer 111 and gate insulating layer 115) between the first upper voltage line VDLb and the initialization voltage line VIL may be damaged or destroyed. In particular, damage or destruction of the insulating layer may occur in a stepped portion of the insulating layer. In this case, there may be an issue in which the first driving voltage line VDL (e.g., the first upper voltage line VDLb) and the initialization voltage line VIL are short-circuited.

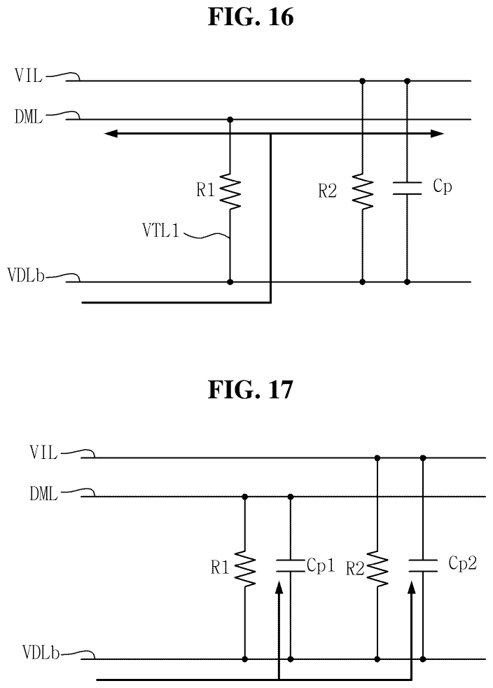

According to some embodiments, the dummy line DML may be disposed to overlap the first upper voltage line VDLb in order to prevent a large amount of charges from accumulating in the overlapping area OVA of the first upper voltage line VDLb and the initialization voltage line VIL. By the dummy line DML, the charges of the first upper voltage line VDLb may be distributed without being collected in the overlapping area OVA of the first upper voltage line VDLb and the initialization voltage line VIL. In other words, the charges of the first upper voltage line VDLb may be distributed to and accumulated in both the initialization voltage line VIL and the dummy line DML. Accordingly, the short circuit between the first upper voltage line VDLb and the initialization voltage line VIL may be prevented by the dummy line DML. This charge distribution principle will be described in more detail with reference to FIGS. 16 and 17, which will be described later.

During the manufacturing process of the display device 1 before the dummy panel DMP is removed, the dummy line DML may remain connected to the first voltage transmission line VTL1. Accordingly, the dummy line DML may be equipotential with the first voltage transmission line VTL1 during the manufacturing process of the display device 1. For example, the dummy line DML receives the first driving voltage from the first voltage transmission line VTL1, so that the voltage of the dummy line DML and the voltage of the first voltage transmission line VTL1 may be at equal potential. Accordingly, charges due to the static electricity generated during the manufacturing process of the display device 1 may be prevented from being collected in a specific area.

FIG. 15 is a plan view of a display device in which the dummy panel DMP is removed from the base substrate of FIG. 14.

When the dummy panel DMP is removed from the base substrate through the aforementioned scribing process, a part of the first upper voltage line VDLb, a part of the second driving voltage line VSL, a part of the first data line DL1, a part of the initialization voltage line VIL, a part of the second data line DL2, a part of the third data line DL3, a part of the dummy line DML, the first data transmission line DTL1, the second data transmission line DTL2, the third data transmission line DTL3, the gate transmission line GTL, the first voltage transmission line VTL1, the second voltage transmission line VTL2, the third voltage transmission line VTL3, the inspection pad electrode PT, and the test transistor TR on the dummy panel DMP may be removed as shown in FIG. 15.

Therefore, as shown in FIG. 15, a part of the first upper voltage line VDLb, a part of the second driving voltage line VSL, a part of the first data line DL1, a part of the initialization voltage line VIL, a part of the second data line DL2, a part of the third data line DL3, and a part of the dummy line DML may be disposed on the display panel 100.

According to some embodiments, the dummy line DML may be maintained in a floating state as shown in FIG. 15. For example, the dummy line DML may be disposed in the non-display area NDA of the display panel 100 in a floating state in which it is not directly connected to any signal line.

According to some embodiments, one end EG1 of the dummy line DML may be disposed to correspond to one end EG2 (or edge) of the first substrate 110 as shown in FIG. 15. For example, the one end of the dummy line DML may be disposed to coincide with the one end of the first substrate 110. This is due to the fact that the dummy line DML and the first substrate 110 are cut together along the scribing line SCL.

According to some embodiments, one end of the dummy line DML may have a carbonized region. The carbonized region may have a black color. For example, when a laser is used in the scribing process, a part of the dummy line DML (e.g., one end of the dummy line DML) cut by the laser along the scribing line SCL may be carbonized by irradiation of the laser.

As shown in FIG. 15, even after the removal process of the dummy panel DMP, the dummy line DML still overlaps the first upper voltage line VDLb. Therefore, it is possible to prevent the destruction of the insulating layer and resulting short circuit between the first upper voltage line VDLb and the initialization voltage line VIL caused by charge accumulation due to static electricity as described above.

FIG. 16 is a diagram for describing charge distribution by the dummy line DML of FIG. 14.

As shown in FIG. 16, the dummy line DML and the first upper voltage line VDLb may be connected to each other by the first voltage transmission line VTL1. Accordingly, there may be an effect of increasing the area of the first upper voltage line VDLb. Therefore, the charges accumulated in the first upper voltage line VDLb due to static electricity may be distributed, thereby reducing the charge density. Accordingly, the aforementioned issue due to static electricity (e.g., a short circuit between the first upper voltage line VDLb and the initialization voltage line VIL) may be prevented.

As shown in FIG. 16, charges generated by static electricity of the first upper voltage line VDLb may be discharged to the dummy line DML through the first voltage transmission line VTL1. Arrows in FIG. 16 indicate a movement path of charges.

In FIG. 16, a first resistor R1 refers to the resistance between the first upper voltage line VDLb and the dummy line DML that are connected by the first voltage transmission line VTL1, a second resistor R2 refers to the resistance between the first upper voltage line VDLb and the initialization voltage line VIL, and a capacitor Cp refers to the capacitance between the first upper voltage line VDLb and the initialization voltage line VIL.

FIG. 17 is a diagram for describing charge distribution by the dummy line DML of FIG. 15.

As shown in FIG. 17, the first resistor R1 and a first capacitor Cp1 may be formed between the first upper voltage line VDLb and the floating dummy line DML, and the second resistor R2 and a second capacitor Cp2 may be formed between the first upper voltage line VDLb and the initialization voltage line VIL. By the floating dummy line DML, the charges of the first upper voltage line VDLb may be distributed without being collected in the overlapping area OVA of the first upper voltage line VDLb and the initialization voltage line VIL. In other words, the charges of the first upper voltage line VDLb may be distributed to and accumulated in both the first capacitor Cp1 and the second capacitor Cp2. Accordingly, the short circuit between the first upper voltage line VDLb and the initialization voltage line VIL may be prevented by the dummy line DML.

As shown in FIG. 17, the charges generated by static electricity of the first upper voltage line VDLb may be distributed to and accumulated in both the first capacitor Cp1 and the second capacitor Cp2. Arrows in FIG. 17 indicate a movement path of charges.

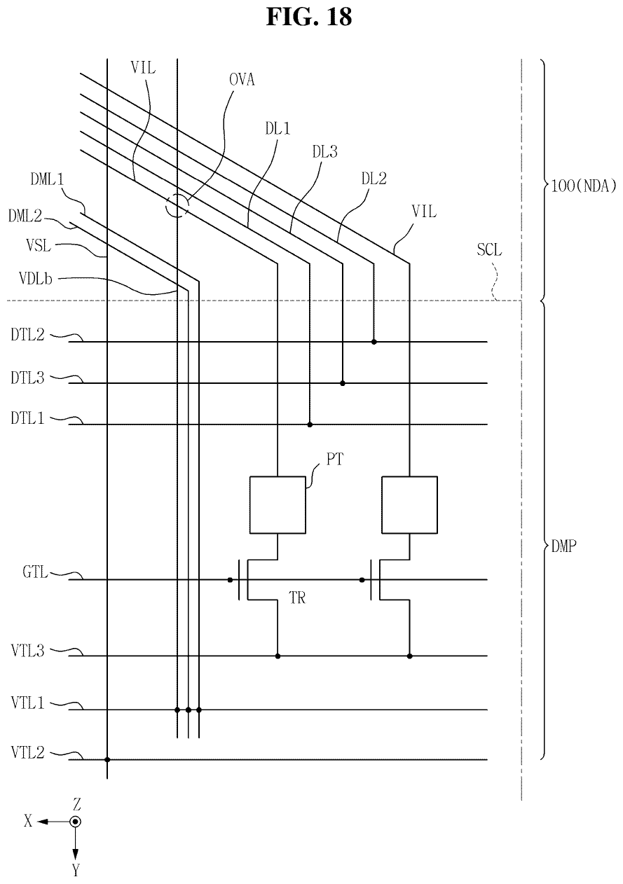

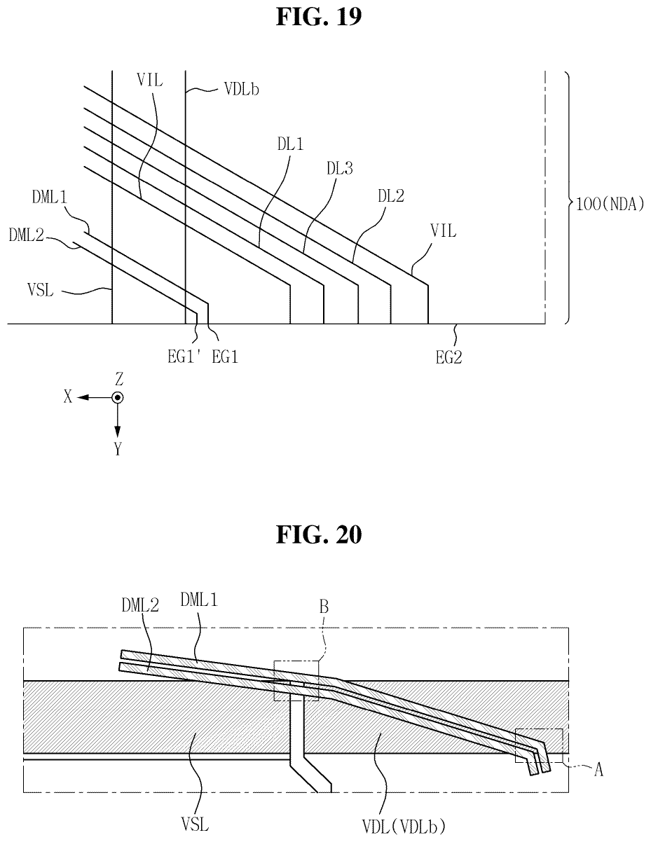

FIG. 18 is a plan view of the dummy line DML and peripheral components in a base substrate including the display panel 100 according to an embodiment. FIG. 19 is a plan view of a display device in which the dummy panel DMP is removed from the base substrate of FIG. 18.

The display device of FIGS. 18 and 19 is different from the aforementioned display device of FIGS. 14 and 15 in that it includes two dummy lines DML1, DML2. The following description is directed to the difference.

As shown in FIGS. 18 and 19, the display device may include the first dummy line DML1 and the second dummy line DML2.

Since the first dummy line DML1 is the same as the dummy line DML shown in FIGS. 14 and 15, description of the first dummy line DML1 is substituted with the description of the dummy line DML shown in FIGS. 14 and 15.

The second dummy line DML2 may be disposed adjacent to the first dummy line DML1. The second dummy line DML2 may be disposed in parallel with the first dummy line DML1. Similarly to the first dummy line DML1, the second dummy line DML2 may overlap the first upper voltage line VDLb and the second driving voltage line VSL on the display panel 100.

The first and second dummy lines DML1 and DML2 may not be connected to each other. However, when the first and second dummy lines DML1 and DML2 are connected to the first upper voltage line VDLb via the insulating layers 111 and 115 that have been damaged, the first dummy line DML1 may be indirectly connected to the second dummy line DML2 via the first upper voltage line VDLb.

Thus, more charges of the first upper voltage line VDLb may be distributed through the plurality of dummy lines DML1 and DML2. Accordingly, damage and destruction of the insulating layer due to static electricity may be more effectively prevented.

According to some embodiments, one end EG1′ of the second dummy line DML2 may be disposed to correspond to the one end EG2 (or edge) of the first substrate 110 as shown in FIG. 19. For example, one end of the second dummy line DML2 may be disposed to coincide with one end of the first substrate 110. This is due to the fact that the second dummy line DML2 and the first substrate 110 are cut together along the scribing line SCL.

According to some embodiments, the one end EG1′ of the second dummy line DML2 may have a carbonized region. The carbonized region may have a black color. For example, when a laser is used in the scribing process, a part of the dummy line (e.g., the one end EG1′ of the second dummy line DML2) cut by the laser along the scribing line SCL may be carbonized by irradiation of the laser.

According to some embodiments, the display device may include three or more dummy lines.

FIG. 20 is a diagram illustrating a result of a simulation to which the configuration of a display device according to an embodiment is applied.

As shown in FIG. 20, the first dummy line DML1 and the second dummy line DML2 may overlap the first driving voltage line VDL (e.g., the first upper voltage line VDLb of the first driving voltage line VDL).

In this case, the magnitude of the electric field in first region A of the first upper voltage line VDLb was about 1.4 MV/m, and the magnitude of the electric field in second region B between the first upper voltage lines VDLb was about 1.3 MV/m. For example, these values may be significantly lower than the values in corresponding overlapping regions A and B in a comparative disclosure that does not include the dummy line DML. For example, in the comparative disclosure, the electric field in first region A is 86 MV/m, and the electric field in second region B is 33 MV/m.

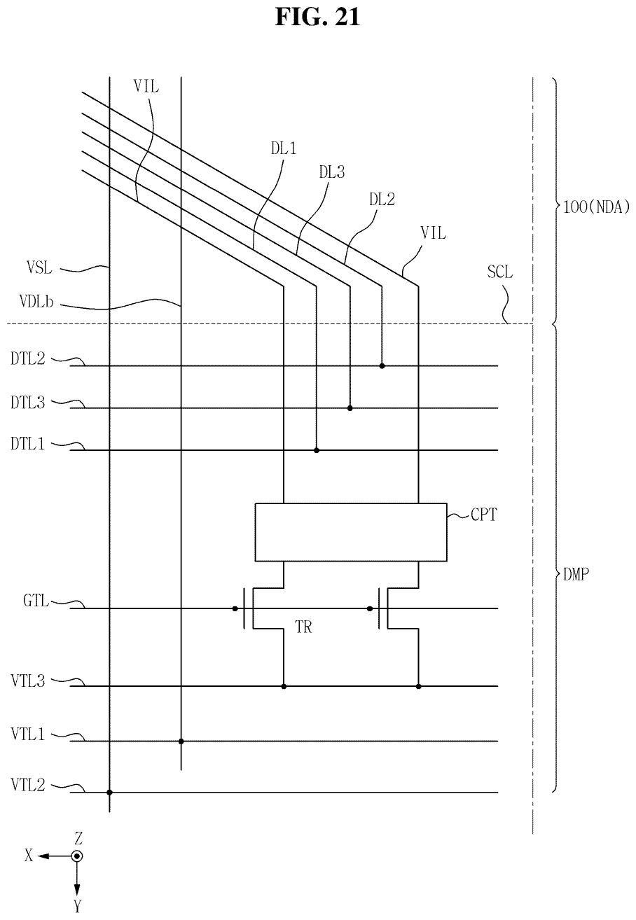

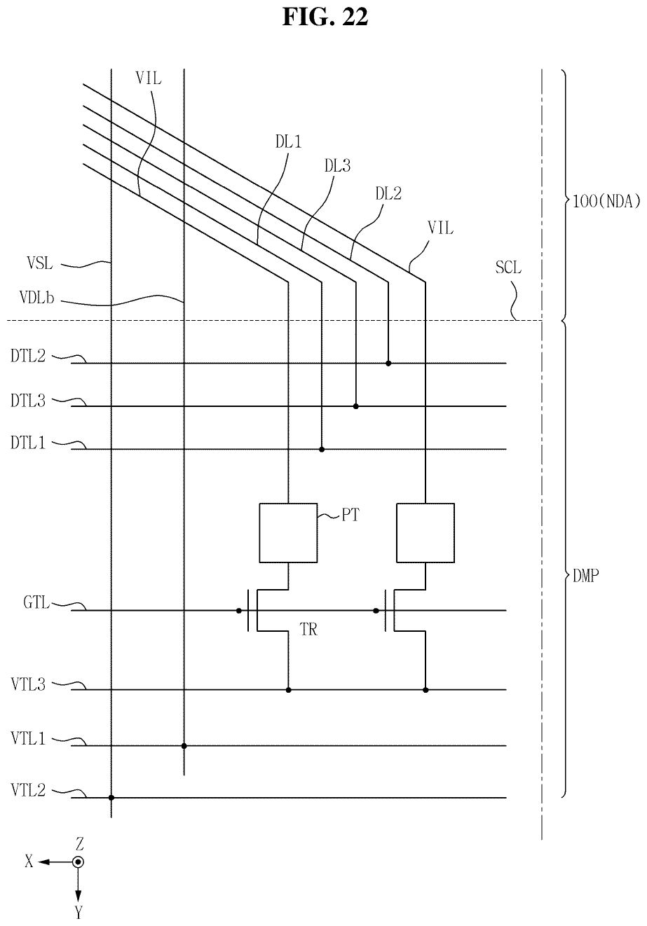

FIGS. 21 and 22 are plan views of a display device according to an embodiment.

The display device of FIGS. 21 and 22 is different from the display device of FIG. 14 in the dummy line DML and the inspection pad electrode PT. The following description is directed to the differences.

As shown in FIG. 21, one common inspection pad electrode CPT may be commonly connected to each of the drain terminals of the test transistors TR on the dummy panel DMP. In this case, the area of the common inspection pad electrode CPT may be increased. Accordingly, static electricity generated in the initialization voltage line VIL may be effectively discharged.

In order to determine whether each pixel is defective or not, the inspection pad electrodes PT need to be separated from each other and connected to the respective test transistors TR. Therefore, after removal of the static electricity, the common inspection pad electrode CPT may be separated into the plurality of inspection pad electrodes PT. For example, in a patterning step of the aforementioned anode electrode (e.g., the first anode electrode AE L), the common inspection pad electrode CPT may be etched to be separated into the plurality of inspection pad electrodes PT. In other words, the anode electrodes AE1, AE3, and AE3 and the plurality of inspection pad electrodes PT may be formed together through the same patterning process (e.g., a photolithography process and an etching process).

It will be able to be understood by one of ordinary skill in the art to which the present disclosure belongs that the present disclosure may be implemented in other specific forms without changing the technical spirit or essential features of the present disclosure. Therefore, it is to be understood that the exemplary embodiments described above are illustrative rather than being restrictive in all aspects. It is to be understood that the scope of the present disclosure are defined by the claims rather than the detailed description described above and all modifications and alterations derived from the claims and their equivalents fall within the scope of the present disclosure.

What is claimed is:

1. A display device comprising:
a substrate having a display area and a non-display area;
a pixel disposed in the display area;
a first driving voltage line connected to the pixel in the display area, and extending to the non-display area;
an initialization voltage line connected to the pixel in the display area, extending to the non-display area and overlapping the first driving voltage line in the non-display area; and
a dummy line disposed in the non-display area, and overlapping the first driving voltage line.

2. The display device of claim 1, wherein the dummy line has a floating state.

3. The display device of claim 1, wherein the dummy line is disposed on a same layer as the initialization voltage line.

4. The display device of claim 1, wherein the first driving voltage line comprises:
a first lower voltage line disposed on the substrate, and extending in a first direction; and
a first upper voltage line on the first lower voltage line, the first upper voltage line being connected to the first lower voltage line, and extending in a second direction intersecting the first direction.

5. The display device of claim 4, wherein the dummy line overlaps the first upper voltage line.

6. The display device of claim 4, wherein the dummy line is connected to the first lower voltage line.

7. The display device of claim 4, wherein the dummy line is disposed on a same layer as the first lower voltage line.

8. The display device of claim 4, further comprising an insulating layer between the first lower voltage line and the first upper voltage line,
wherein the dummy line is disposed between the substrate and the insulating layer.

9. The display device of claim 1, wherein the dummy line is disposed adjacent to the initialization voltage line.

10. The display device of claim 1, wherein one end of the dummy line is disposed at one end of the substrate.

11. The display device of claim 10, wherein the one end of the dummy line comprises a carbonized region.

12. The display device of claim 1, wherein the dummy line has a width larger than a width of the initialization voltage line.

13. The display device of claim 1, further comprising a plurality of dummy lines comprising the dummy line.

14. The display device of claim 13, wherein the plurality of dummy lines each overlap the first driving voltage line, and
the plurality of dummy lines are not connected to each other.

15. The display device of claim 1, further comprising a second driving voltage line overlapping the dummy line and the initialization voltage line in the non-display area.

16. A display device comprising:
a substrate having a display area and a non-display area;
a pixel disposed in the display area;
a first driving voltage line disposed in the display area and the non-display area;
an initialization voltage line disposed in the display area and the non-display area, and overlapping the first driving voltage line in the non-display area; and
a dummy line overlapping the first driving voltage line in the non-display area.

17. The display device of claim 16, wherein the dummy line has a floating state.

18. The display device of claim 16, wherein the dummy line is disposed on a same layer as the initialization voltage line.

19. The display device of claim 16, wherein the first driving voltage line comprises:
a first lower voltage line disposed on the substrate, and extending in a first direction; and
a first upper voltage line on the first lower voltage line, the first upper voltage line being connected to the first lower voltage line, and extending in a second direction intersecting the first direction.

20. The display device of claim 19, wherein the dummy line overlaps the first upper voltage line.

21. The display device of claim 19, wherein the dummy line is connected to the first lower voltage line.

22. The display device of claim 19, wherein the dummy line is disposed on a same layer as the first lower voltage line.

23. The display device of claim 19, further comprising an insulating layer between the first lower voltage line and the first upper voltage line,
wherein the dummy line is disposed between the substrate and the insulating layer.

24. The display device of claim 16, wherein the dummy line is disposed adjacent to the initialization voltage line.

25. The display device of claim 16, wherein one end of the dummy line is disposed at one end of the substrate.

26. The display device of claim 25, wherein the one end of the dummy line comprises a carbonized region.

27. The display device of claim 16, wherein the dummy line has a width larger than a width of the initialization voltage line.
